(19) United States
(12) Patent Application Publication
(10) Pub. No.: US 2020/0090963 A1
(43) Pub. Date: Mar. 19, 2020

(54) APPARATUS FOR AND METHOD OF MANUFACTURING AN ARTICLE USING PHOTOLITHOGRAPHY AND A PHOTORESIST

(71) Applicant: CALLAGHAN INNOVATION, Lower Hutt (NZ)

(72) Inventors: Andrea Jocelyn Bubendorfer, Lower Hutt (NZ); Andrew David Best, Lower Hutt (NZ)

(21) Appl. No.: 16/493,897

(22) PCT Filed: Mar. 15, 2018
(86) PCT No.: PCT/NZ2018/050030

§ 371 Date: Sep. 13, 2019

(30) Foreign Application Priority Data
Mar. 15, 2017 (NZ) 730112

(51) Int. Cl. H01L 21/67; G03F 7/20; G03F 7/16

(52) U.S. Cl. CPC H01L 21/67092; H01L 21/67115; G03F 7/161; G03F 7/2032; H01L 21/6715

(57) ABSTRACT

An apparatus configured to manufacture an article using a photoresist comprising photoresist material, the apparatus comprising:
a. a housing configured to receive the photoresist and locate the photoresist in at least one operational position in the housing;
b. an exposure system configured to emit radiation which is incident on the photoresist material when in the operational position, to induce a change in one or more properties of the area(s) of the photoresist material exposed to the radiation; and
c. a heater configured to heat the photoresist material to cure the photoresist material to the substrate when the photoresist is in the operational position, or is in a different operational position in the housing; wherein
d. the housing is radiation excluding such that external radiation cannot enter the housing at least to the extent that the external radiation is sufficiently excluded from the housing to prevent, or minimise polymerisation of the photoresist material, and further wherein the housing is a clean housing configured to prevent unwanted contamination from entering the housing, at least when the photoresist is located in the or each operational position.

The apparatus may be a floor standing or desktop apparatus, for producing single or multi-layered articles.

### BACKGROUND OF THE DISCLOSURE

### Field of the Disclosure

The present disclosure generally relates to an apparatus for and method of manufacturing an article using photolithography and a photoresist. In some examples the apparatus and method use a dry film photoresist. The present disclosure stems from work based on photoresists in sheet or film form. An example photoresist is as described in patent application US2006/0257785, the entire contents of which are incorporated herein by reference.

### Description of the Related Art

Photolithography is a well-known manufacturing process used in microfabrication to produce relatively thin planar parts using a substrate. Light from a light source is incident on a light sensitive material known as a photoresist. The light is incident via a pattern, also known as a photomask, which directs light to particular areas of the photoresist, the light causing a change in the solubility of the photoresist material in those desired areas, such that the exposed or non-exposed areas can be removed via subsequent chemical/heat treatment. In some cases new material can be deposited onto the areas where the photoresist material has been removed and the process repeated, building up layers of material in the desired pattern.

In one prior art example, a liquid solution of photoresist material is spun onto a wafer or substrate and then prebaked. The photoresist is then exposed to light in the pattern desired. This causes a chemical change in the photoresist which allows the photoresist to be removed via a developer which is typically a liquid such as sodium hydroxide solution for a positive resist, or a solvent such as propylene glycol monomethyl ether acetate for a negative resist. Typically a negative photoresist is baked before the developer is applied. A positive photoresist is one where the photoresist is made more soluble by exposure to light and is removed by the developer. A negative photoresist is one in which the unexposed areas are removed by the developer. The negative photoresist may be chemically amplified or not. An image reversal resist, which may be used for either positive or negative toned patterning may also be used. There can be further post developing steps such as hard baking after the developer is applied, and/or etching whereby part of the substrate is removed in the areas where the photoresist has been removed.

It is also known to provide a photoresist material as a composite film comprising a polymer film and a dried coating of photoresist material, which composite film is itself applied to a substrate using heat and pressure. The polymer film can then be removed, leaving the photoresist material on the substrate. Such composite films are typically known as dry film photoresists. An example of such a dry film photoresist is disclosed in US2006/0257785 as described above. Such a dry film photoresist is typically supplied as a photoresist material sandwiched between a base polymer film/sheet and a protective cover film/sheet. The polymer film may, depending on its material and configuration, itself function as a substrate during the photolithographic process. Such dry film photoresists can be easier to handle than the liquid forms, can enable different substrate material to be used, can be thicker, and can be processed more quickly.

Nonetheless, whether conventional or dry film photoresists are used, there can be considerable difficulty, precision, time and expense in producing structures using the above described process, and production of free-standing parts has typically been difficult to achieve. Typically a relatively large and expensive processing plant is required with each process step being very precisely controlled. Typically photoresist has to be handled throughout in cleanroom conditions, which are in practice difficult and expensive to achieve, and the light application step requires a yellow room such as a bespoke safe-light cleanroom where blue, violet and ultra-violet light is absent (a “yellow room”). Great care must be taken in handling the photoresist material such that it is not inadvertently exposed to unwanted radiation or contamination and this necessitates very precisely controlled operating conditions and manufacturing plant. Photoresists are also typically used to produce very high resolution articles, which themselves have to be very carefully and precisely processed and handled. The cost of producing articles using this process can therefore be very high.

### SUMMARY OF THE DISCLOSURE

It is an object of the present disclosure to provide an apparatus and method for manufacturing an article using photolithography and one or more photoresists, and/or that will alleviate one or more of the above problems and/or that will at least provide the public with a useful choice.

Accordingly in one aspect the disclosure may broadly be said to consist of an apparatus configured to manufacture an article using a photoresist comprising photoresist material on a substrate, the apparatus comprising:
a housing configured to receive the photoresist and locate the photoresist in at least one operational position in the housing;
an exposure system configured to emit radiation which is incident on the photoresist material when in the operational position, to induce a change in one or more properties of the area(s) of the photoresist material exposed to the radiation; and
a heater configured to heat the photoresist material to cure the photoresist material to the substrate when the photoresist is in the operational position, or is in a different operational position in the housing; wherein
the housing is radiation excluding such that external radiation cannot enter the housing at least to the extent that the external radiation is sufficiently excluded from the housing to prevent, or minimise polymerisation, and further wherein the housing is a clean housing configured to prevent unwanted contamination from entering the housing, at least when the photoresist is located in the or each operational position.

The housing may be configured to be UV excluding, and/or to exclude any other wavelength or range of wavelengths of radiation.

The apparatus may comprise components, assemblies and/or combinations of components and/or assemblies configured to provide any one or more of:
a) controlled actuation for the purpose of photoresist combination and layering;
b) controlled separation of processed photoresist from unprocessed photoresist;
c) removal of processed photoresist from a defined area of processing;
d) alignment and placement of the photoresist controlled.

In some examples the apparatus may be configured to use a dry film photoresist and/or may be configured to receive photoresist comprising one or more removable cover sheets, the apparatus being configured to remove the cover sheets prior to the photo resist reaching the operational position.

The apparatus may be dimensioned so as to be hand portable. The apparatus may be dimensioned and configured as a desk-top apparatus, or at least to be floor mounted. In some examples the overall external dimensions of width, height and length of the apparatus may each be less than 1 m, and in some examples less than 0.75 m, that is, approximately the size of an office type floor standing laser printer.

The radiation excluding/blocking housing may be configured to allow a portion of non-damaging visible light to be seen, thereby providing direct visible feedback as to the current status of the operation of the apparatus to the user. In other words the status of the processing of the photoresist may be safely observed externally of the housing. In other examples, the apparatus may be configured to generate a visual or audible signal indicative of the status of processing.

In some examples, the apparatus is configured to manufacture an article with feature sizes of 0.5 microns or less, 2 microns or less, four microns or less, or 20 microns or less, and/or a scale of at least 1 cm, 5 cm, 10 cm, 15 centimetres, or 50 cm or more. The resolution achieved may be determined in relation to the pixel size of the exposure system.

The exposure system preferably comprises an exposure source. The exposure source can be any suitable radiation source such as a light source. The light source may comprise any one or more of a UV fluorescent tube or bulb, an LED or LED array, a laser, and/or a projector such as a digital micromirror device (DMD), for example. The exposure source can emit radiation at any high energy electromagnetic frequency including X-ray, deep, mid or near UV, through to visible light. The exposure source may be configured to emit radiation in a wavelength range of 300-450 nm, and in some examples in a range of 365-405 nm. The exposure source may be collimated. The collimation may be performed by a lens, or paraboloid reflector, for example. The exposure source can be positioned within the apparatus either above or below the substrate of the photoresist and can emit radiation onto either or both of the topside or the underside of the substrate.

The exposure system may include one or more radiation manipulators configured to manipulate the radiation between the exposure source and the photoresist. The radiation manipulators could include any one or more of, for example, a mirror, a digital mirror, a prism, a lens, and/or a beam splitter. In some examples multiple radiation manipulators are provided. The multiple radiation manipulators may be provided in series or parallel configuration along the radiation path between the exposure source and the photoresist, that is, the operational position of the apparatus.

The exposure system may comprise one or more passive radiation manipulators and/or one or more dynamic or active radiation manipulators.

The exposure system may include one or more dynamic radiation manipulator configured to manipulate the radiation between the exposure source and the photoresist. The dynamic radiation manipulator could include any one or more of, for example, a digital mirror, an LCD, a galvanometer and/or an optomechanical laser system. In some examples multiple radiation manipulators are provided. The multiple radiation manipulators may be provided in series or parallel configuration along the radiation path between the exposure source and the photoresist. Before and/or after the dynamic radiation manipulator additional manipulators can be included, such as but not limited to, lenses, mirrors, or beam splitters.

In some embodiments, the length of the radiation path between the exposure source and the operational position of the photoresist is adjustable. In such embodiments the apparatus may therefore comprise a radiation path length adjuster configured to move one or both of the operational position of the photoresist and the position of the exposure source. In some embodiments the radiation path length adjuster comprises a platform on which the photoresist is located when in the operational position, the platform being movably mounted within the apparatus. The platform may comprise, or be coupled to, the heater.

In some examples, the platform and exposure source may both be movably mounted on the apparatus. The platform and exposure source may be configured to move together such that movement of the platform also moves the exposure source. The platform and the exposure source may be mounted on a carriage, the carriage being movably mounted on a linear element such as a track.

The heater could comprise any one or more of:
a) a heater plate on which the photoresist is placed when in the operational position;
b) a heater plate configured to be movable into a position adjacent or in contact with the photoresist when in the operational position;
c) an infrared heat source configured to radiate the photoresist; and/or
d) an oven in which the photoresist is located when in the operational condition.

The apparatus may comprises one or more controllers configured to control the exposure system and the heater.

The or one of the controller(s) may be configured to control any one or more of:
a) the intensity, and/or duration and/or timing of the radiation emitted from the exposure system; and/or
b) any one or more of the temperature, duration, timing and/or heating/cooling rate of the heater.
c) an exposure profile and/or a heater profile;
d) actuation elements such as those yielding thermal or mechanical functionality.
e) processing of feedback derived from sensors located in or on the apparatus;
f) the relative position between the exposure system and the operational position;
g) the relative position between the heater and the operational position.

The heater profile may be, for example approximately 10 mins at approximately 100° C. The exposure profile may be approximately 395 nm for approximately four minutes per layer of the 20 μm film. The exposure profile may be dependent on the power of the exposure system.

The controller preferably comprises a user interface. The controller may be configured to receive one or more inputs indicative of one or more properties of the article to be manufactured and/or of the dry film photoresist, and to control the exposure system profile and/or heater profile accordingly. In one example, the controller is configured to receive a single input being the thickness of the dry film photoresist. Any one or more of the input(s) to the controller may be a manual input entered by the user or a measured input determined from one or more sensors provided in or on the apparatus. The controller may be user programmable such that the user can configure one or more parameters of the controller. For example, the controller could control parameters relating to any one or more of:
a) thickness of photoresist (that is, the thickness of layer, in the z or vertical direction);
b) changes to exposure and/or heat profile to optimise processing if required;
c) the status of the apparatus. For example whether the apparatus is in an exposure, heating or cooling part of the process, how long until the program is finished, and rate of heating and/or cooling.

The controller may include one or more microcontrollers. Each controller may comprise any one or more of: an electronic data processor, a manual switched input and a timer.

An interlock may be built into the apparatus preventing hazards to the user such as exposure to the UV or other radiation and/or contact with heat by the user while the apparatus is operational.

The user interface further provides information as to the status of the system, by an illuminated button to indicate exposure, and a heat indicator demonstrating when the heater is operating and hot, or cool and ready to remove resist, by illuminating either red or green accordingly. The user interface may also store pre-programmed recipes and provide user guidance throughout operation of the system. The user interface could be a network based user interface configured to communicate remotely or wirelessly with the apparatus

The apparatus may further comprise a developer unit configured to deliver a developer fluid to the photoresist being processed so as to develop the photoresist after curing by the heater to remove either any photoresist material exposed to the developer fluid, or to remove any substrate. In some examples, the substrates do not have an oxide layer between the substrate and the photoresist. When free-standing structures are made, a PET or other backing sheet is simply mechanically removed, or, if easier for developing depending on the pattern, it may remain in place to support the structures through the development and be removed afterwards. Substrates with oxide layers could also be used with this system.

In some embodiments a tank of developer fluid is provided inside the housing. In other examples, the tank of developer fluid is separate from the apparatus and/or at least in communication with the inside of the housing. In some embodiments the developer fluid is exposed to the photoresist via a dispenser configured to dispense developer fluid onto the photoresist. Developer fluid may be dispensed in a mist or spray through one or more nozzles for example. In other embodiments, the apparatus is configured to soak or bathe the photoresist in developer fluid. This may be achieved in the developer tank or in a secondary tank or bath in fluid communication with the developer tank. The photoresist may be moved from the operational position, into a further operational position being a developer position in which the photoresist can be exposed to the developer fluid. In other embodiments, the photoresist remains in the operational position and developer fluid is subsequently applied to the photoresist after curing by the heater. The developer unit can comprise an integral component of the housing, and may be an internal or external component. The developer unit may be removeably mounted on the housing. A removable developer unit can be removed after use and either replenished with developer fluid or replaced. The developer system could recycle developer by using the inbuilt UV source or another UV source to cross-link and remove unpatterned resist. The developer system could be a zero waste system by extracting uncross-linked material from the developer in such a way that it may be reconstituted for further use, e.g. by precipitation or centrifugation for example.

The developer fluid may comprise hot water or another heated or non-heated fluid. The fluid may melt, or dissolve away bulk uncross-linked material, such that the uncross-linked material is easier to remove. The hot water or other fluid may use surfactants to break up and remove unused material. The fluid may be contained in one or more baths. The bath may be the cartridge in which the photoresist is exposed, or a separate secondary cartridge so as to isolate developer from the user. The fluid may be heated by the heater, or by another heat source which may be internal or external of the housing. The heat source may include a microwave source for example.

In some examples, the exposure system and the heater may be configured to be operative sequentially. In other examples, the exposure system and the heater may be configured to be operative concurrently. The exposure system may therefore be operative to emit radiation whilst the heater is on. The exposure system and heater may each be configured to be switched on and off at the same time as the other, or may be configured to be operative for a period which overlaps with the other.

The apparatus may comprise or further comprise a patterning system configured to enable a desired pattern to be applied to the photoresist. In some examples the patterning system may comprise a pattern formed or depicted on a protective sheet of, or applied to the photoresist. In other examples, the patterning system may comprise one or more photomasks positioned, or configured to be positioned, between the exposure system and the photoresist. The patterning system may be positioned, or configured to be positioned, in direct contact with the photoresist, such that there is no gap or space between the photoresist and the patterning system, either caused by air, or by the thickness of the protective sheet. High resolution structures of four micrometres or less may be formed by laminating directly to a high quality photomask. In other examples, the patterning system may comprise an electronic/optical/digital system configured to generate a pattern on the photoresist. The disclosure therefore includes the use of a glass photomask as a method of patterning, but also the possibility of making photo-patterns, such as films and photo-plates, either with a digital exposure or from another film pattern or photoplate.

In some examples, the photoresist is located in a single operational position during exposure to radiation from the exposure system and during curing by the heater. In other examples the apparatus comprises a plurality of operational positions, each of which is associated with one or more processing step of the apparatus.

In some embodiments, the apparatus is configured to contain only a single photoresist layer, or at least is configured to process only a single photoresist layer at a given time.

In other embodiments the apparatus is configured to contain or store a plurality of photoresist layers. The apparatus may comprise a storage device configured to store a plurality of photoresists. The storage device may be configured to store the plurality of photoresists in a stack. The storage device may be removeably mounted on the apparatus. The storage device may be configured to store the plurality of photoresists in a roll or reel. The roll or reel of photo resists may be removably stored in a storage device comprising a radiation excluding housing comprising an outlet through which the photoresist is fed towards the operational position.

The apparatus may further comprise a photoresist feed device configured to feed one or more photoresists into the operational position within the housing of the apparatus. The feed device may be manually operated or may be automated. For example, the feed device could comprise a movable platform or carriage on which the photoresist is placed and inserted into the housing. A locking device may be provided to lock the photoresist in the operational position, at least until the processing steps are complete. In other examples the feed device may comprise one or more rotating elements, such as rollers or wheels, configured to feed a roll of photoresists into the housing. Multiple rotating elements may be provided, the photoresists being sandwiched between adjacent rotating elements. The or each rotating element may be configured to remove one or more cover sheets from the photoresist. The feed device may comprise at least one moving platform, substrate or belt to move the photoresist to the operational position. In some examples a pair of laterally spaced apart belts are provided, on which the photoresist rests as it is fed from the feed device. The belts may be toothed to engage with, and be driven by, one or more toothed rotating elements.

In some embodiments the apparatus is configured to process only a single photoresist at a given time. The apparatus may be configured to sequentially receive a plurality of photoresists, each photoresist being processed in sequence. When received sequentially, the photoresists may be stored in a storage device of the apparatus, as above. If provided on a strip or roll or reel, this may be fed into the apparatus at the required rate. Such a strip or roll or reel may, in some examples, also be fed out of the apparatus such that the apparatus is configured for continuous throughput of photoresists by running a reel to reel process. Suitable strip/reel feed devices may be provided to control the rate of feed of the photoresists into the apparatus.

In some embodiments, the apparatus is configured to manufacture an article from multiple photoresists. These photoresists may be processed separately or sequentially as above. Once processed, the apparatus may be configured to apply one or more further process steps to the photoresists to produce the article. The one or more further process steps may include one or more cutting, alignment and reassembly steps such that the photoresists are layered together in the correct alignment and orientation, to produce the article.

In an apparatus configured to manufacture an article from multiple photoresists, the apparatus may be operative according to one or more of the following primary process steps wherein each layer of the article is a portion of a sheet or sheets or strip or strips of photoresist:
a) rolling the sheet through the machine;
b) removing the protective cover sheets;
c) exposing the photoresist to a pattern with UV light eg, by projection.
d) blocking radiation underneath the photoresist sheet to prevent unwanted exposure of the photoresist
e) folding or cutting the patterned layer, for example with a heated or non-heated cutter;
f) aligning the folded or cut layer within a stack of previous layers of photoresist by a mechanical, optical or other positioning/alignment mechanism;
g) laminating the folded or cut photoresist to a stack of previous layer(s) of photoresist with a laminator, which may be a hot roll laminator.
h) heating the photoresist stack to cure by cross-linking the layers together to form an integral unit within the unexposed and therefore uncrosslinked material, whereby the uncrosslinked material effectively acts as a support material;
i) removing the support material by washing in developer fluid.

In some embodiments the apparatus is configured to simultaneously process multiple photoresist sheets. In such embodiments, the apparatus may be configured to process only a single photoresist sheet at a given time for part of the process and to simultaneously process multiple photoresist sheets for a different part of the process. For example, the apparatus may be configured such that only a single photoresist sheet at a time is exposed to radiation from the exposure means, but multiple photoresists are simultaneously cured by the heater.

In some embodiments multiple photoresists may be provided on a sheet, the apparatus being be configured to sequentially expose and subsequently cure the multiple photoresists independently, the apparatus being further configured to recombine the patterned elements of the multiple photoresists after exposure to form multilayer structures. In other examples, the apparatus may be configured to simultaneously expose multiple photoresists.

The apparatus may comprise one or more coversheet removal mechanisms configured to provide controlled removal of one or more coversheets of the photoresist prior to the photoresist being moved to the operational position. The removal mechanisms may comprise driven rotating elements, such as gearing/rollers onto which the coversheets are rolled.

The apparatus may comprise an article removal mechanism configured to remove the article from the apparatus, or at least from the operational position.

The apparatus may comprise a laminator configured to combine processed material through either cold or heated lamination. The laminator may be a hot roll laminator.

The apparatus may comprise a cutter or separator configured to separate processed material from any material within the region of processing, that is, material still being processed, still to be processed, and/or material in the operational position.

The apparatus may comprise an isolator configured to isolate the processed material from the unprocessed material.

The apparatus may comprise a mechanism for the controlled compression/seizing of material motion which allows for regional processing. This mechanism may comprise a clamping mechanism. The clamping mechanism may comprise a clamping plate configured to selectively clamp the photoresist in the operational position. The clamping plate may be movably mounted on the apparatus so as to be movable between clamping and non-clamping positions.

According to another aspect of the disclosure there is provided a photoresist configured for use with the apparatus of the above aspect of the disclosure, the photoresist comprising photoresist material sandwiched between cover sheets comprising a base sheet and a protecting film. The base sheet and protective sheet are known as carrier or cover sheets. Each film/sheet may be removable. The base sheet may itself be applied to a rigid substrate, or may itself function as a substrate. The carrier sheets may be used to maintain smoothness and flatness of the photoresist prior to as well as during exposure and heating. This may be particularly useful if the article to be manufactured is formed from multiple photoresists stacked in layers, where the carrier sheet holds the uncross-linked photoresist flat during processing, enabling subsequent layers to be laminated evenly and preventing slumping of patterns in those subsequent layers.

The substrate may be formed from any suitable material. Example materials include silicon, metal(s), polymer(s), paper(s) or other fabric(s), epoxies, or a base layer of SUEX® as manufactured by DJMicroLaminates (formerly known as DJ DevCorp), or EMS series dry film resists, or other photoresists, including other dry film resists or dried resist films coated from solution. Polymer substrates may be particularly advantageous due to their increased bonding affinity to photoresists, low cost, machineability and optical transparency. A base layer of photoresist bonded to a polymer substrate gives high adhesion where required, such as for the production of micromoulds.

According to another aspect of the disclosure there is provided a photoresist cartridge configured for use with the apparatus of the above aspect of the disclosure, the cartridge comprising photoresist material sandwiched between a base sheet and a protecting film, the base sheet being laminated to a rigid substrate such that the photoresist and rigid substrate together comprise part of the cartridge which is removeably insertable into the housing of the apparatus and into the operational position.

The cartridge and the housing are configured to interface so as to prevent the ingress of UV light into the housing, at any stage including insertion and removal of the cartridge and when the cartridge is in the operational position. The cartridge is further designed so as to protect the photoresist from contamination at any stage until or including developing is carried out, and from curing radiation until it is in the operational position.

The design of the cartridge is modular such that it can be configured for different applications, such as the formation of free-standing structures, electroplating moulds or soft lithographic moulds, and for different substrates as earlier described.

The apparatus may comprise a cartridge feed device configured to automatically load the cartridge into the apparatus. The apparatus may comprise a cartridge ejection device configured to automatically eject the cartridge from the apparatus. The cartridge is designed such that UV ingress to the apparatus or incident on the photoresist is prevented during loading and/or ejection.

The cartridge, and in particular the rigid substrate, may be provided with interaction features that enable the cartridge to interact with the apparatus. Such interaction features of the cartridge may comprise any one or more of:
a) a guide feature configured to guide the cartridge into the housing;
b) an orientation feature configured to orientate the cartridge correctly as the cartridge is inserted into the housing;
c) a drive feature configured to enable the cartridge to be driven into the housing via a suitable drive mechanism of the apparatus, or by the system microcontroller;
d) a locking feature configured to enable the cartridge to be releasably locked in the or each operational position inside the cartridge;
e) an access feature configured to enable insertion of the cartridge into the housing to be permitted or prevented. Such a feature could comprise a mechanical or electromechanical feature configured to engage with a feature of the apparatus to prevent the cartridge being inserted into the housing in certain circumstances. Such circumstances might include the cartridge being a cartridge that is incompatible with the apparatus, or if another cartridge is already in the operational position inside the cartridge, or if there is a fault with the apparatus.
f) An identification feature configured to enable the apparatus to identify the cartridge during or after insertion into the apparatus. Such a feature may enable initiation of the processing of the photoresist once the cartridge has been identified. Such initiation may be automated for example.

Any or all of the above features may comprise a mechanical feature such as a mechanical formation or component formed integrally with, or attached to the cartridge. Any or all of the above features may alternatively or additionally comprise an electronic feature such as a RFID or other electronic tag which is read by one or more electronic tag reader(s) on the apparatus.

The photoresist cartridge may comprise one or more keyed or alignment elements to form inbuilt mechanical alignment for multilayer patterning. In this example, an article may be formed from multiple stacked photoresists, the correct alignment of which is ensured by engagement of the keyed elements either with each other, or with a keying element provided in the housing. In other examples alignment can be facilitated using other techniques, for example, as described below by controlling the tension of the photoresist, or by keeping the projector and photoresist moving together.

According to another aspect of the disclosure there is provided a system for manufacturing an article using photoresist comprising a photoresist layer, the system comprising the apparatus of any of the above aspects of the disclosure, and a photoresist or photoresist cartridge of any of the above aspects of the disclosure. The apparatus may be of a modular consideration whereby upgrades or different applications or configurations or modules are interchangeable and may be added or removed.

According to another aspect of the disclosure there is provided a method of manufacturing an article using a photoresist comprising a photoresist, the method comprising steps of:
inserting the photoresist into a housing of a manufacturing apparatus;
using an exposure system in the housing to emit radiation which is incident on the photoresist material when in the operational position, to induce a change in one or more properties of the area(s) of the photoresist material exposed to the radiation; and
controlling a heater, also in the housing, to subsequently heat the photoresist material to cross link the photoresist material to the substrate; wherein
the housing is radiation excluding such that external radiation cannot enter the housing at least to the extent that the external radiation is sufficiently excluded from the housing to prevent, or minimise polymerisation of the photoresist, at least when the photoresist is present, and further wherein the housing is a clean housing configured to prevent unwanted particles and/or other contaminants from entering the housing.

The photoresist can be either used as received as a dry film photoresist, or may be subject to a pre-processing step whereby the apparatus dries a liquid photoresist by removal of the solvent, such that the formed dry photoresist can then be processed as above. The apparatus could use the heater to carry out this pre-processing drying step.

The method may comprise using a photoresist comprising of photoresist material sandwiched between a base sheet and a protecting sheet, or other photoresist such as bare photoresist deposited by means such as spin-coating, dip-coating, doctor blading or other. For example, slot die coating is a used technique to deposit thin films by drawing a liquid material along a substrate, using an edge to provide a highly controlled thickness for a uniformly thick film. Any photoresist can be used in principle, provided that by the time of activation of the exposure system, the photoresist is dry.

The base sheet and/or protective sheet of the photoresist or photoresist cartridge may function as a support material specifically to reduce internal stress and maintain smoothness and flatness during processing, in particular so that high aspect ratio features are not stressed or under stiction, and so that a flat, level support is created for the lamination of subsequent potential layers. High aspect ratio features may be those that have a significantly greater height than width, typically at least a 5:1 ratio. If a relatively tall and thin structure is produced as part of a design, it typically requires external support to keep it from moving around (lozenging).

One of the films may comprise a UV antireflective material. Such a material may be useful in eliminating a scatter surface of the photoresist and preventing unwanted reflections, thereby improving the resolution of the articles. The antireflective material could be the base carrier sheet or the cartridge.

SU-8 liquid photoresist and its dry formulation SUEX are known for their ability to produce exceptionally vertical sidewall structures which is useful in many applications. However, these vertical sidewall structures may be hard to demould. Therefore the apparatus above may be configured to deliberately taper structure side-walls from highly vertical, to produce structures which are much more easily removed from moulds. In demoulding structures, a tapered article is easier to remove from a master due to the reduced static friction.

Conventional photolithographic facilities use photomasks or laser direct write systems, to expose the selected areas of photoresist. Using an existing photomask for the pattern can significantly reduce the cost of production but requires the former preparation of that mask, increasing turnaround time. In contrast laser direct systems tend to be very expensive, but allow near immediate processing. Therefore the apparatus above may be configured to use alternative methods of patterning for “on-the-fly” prototyping, such as laser printing, dynamic light projection, reduction imaging or DVD writing, which processes may be carried out at relatively low cost, providing significant advantages to conventional mask lithography.

The conventional process for releasing microstructures in photolithography is to carry out a chemical etch to remove the substrate after processing the material. However, as the carrier sheets used with the dry film photoresist come with a release coating, one or both of these carrier sheets may then function as a debonding material, for the fast and easy removal of fabricated articles after processing, allowing the production of free-standing structures such as componentry or stencils without the need for etching. An example of this is in the production of articles such as a free-standing microgear, which would typically not be a viable structure to produce by conventionally photolithography due to the need to remove the substrate by removal of layers.

One or both carrier sheets may comprise a patternable surface for direct contact with the photoresist. This may reduce the time and cost required for generating a separate photoplate or photomask. The patternable surface also eliminates air gaps and interfaces created by the carrier sheet, between the photoresist and the exposure system that cause UV scatter and lower resolution. The apparatus may be supplied with, or configured to be used with prepatterned photoresist sheets.

The patterned carrier sheet is typically lower resolution than a photoplate, but it eliminates either the photoresist sticking to the photoplate, while still leaving air gaps that cause scatter, or alternately exposing through a carrier sheet, with the reduction in resolution that occurs from the two interfaces and the thickness of the 40+ micron cover sheet, as well as the surrounding air gaps. Consequently, even though the patterned carrier sheet may be lower resolution than a photoplate, by direct contact with the photo resist the performance is improved. For very high resolution with a pattern, the photomask could be used in place of the carrier sheet, with the pattern side laminated to form intimate contact with the photoresist.

One or both carrier sheets may comprise an adherent surface configured to provide conformal mask over regions of the photoresist that require protection. This may be useful if the article to be manufactured is a circuit board or other electronic or delicate component. Such a film may comprise any of a highly transparent print sheet, sticker, decal, temporary tattoo sheet, microfiche or microfilm for example. Such a conformal mask could be printed in multi-toned grey scale, thus forming shaped, rather than vertical edges.

The method may further comprise steps of using the base and protective sheets to keep the photoresist flat until curing is complete; removing the base and protective sheets prior to developing, and subsequently using the developed photoresist as a base layer to support additional layers, which can then be patterned without slumping.

The method may allow the fabrication of aligned multilayer structures by a method that comprises of the steps of heating the photoresist to semi-cure a pattern only until a visible image is formed; then using the early visible image as an inbuilt reference maker to align one or more layers of the photoresist with another layer of the photoresist, and then subsequently fully curing the multiple layers of photoresists to cure together into a single cross-linked structure by use of lamination, heat, pressure and/or plasma assistance for example. This may help to achieve high bond strength and good alignment where multiple photoresists are used to form the article.

The method may comprise a step of recombining multiple exposed and cured photoresists such that the photoresists occupy multiple planes or are inclined relative to one another, to produce a 3D structure. Additionally or alternatively such a step could be used to bond to solid blocks of epoxy (the base material of the negative photoresist) such that the articles produced are not limited to thin planar structures, or multi-layered flat laminated structures. One example could be a microscale pressure sensor that has relatively large relatively thick vertical side walls that could be assembled with relatively thick blocks of epoxy bound to a thin deformable membrane in a perpendicular plane. Another example could be the basis of an accelerometer sensor that used a fine microstructure coating on the walls of larger unpatterned blocks of epoxy.

The method may comprise a step of forming an active structure such as a cantilever, plate, bridge, or membrane, the four main examples of MEMS springs, for example, widely used for miniaturised sensors. These structures may be produced, by selectively bonding part of a layer of one photoresist to another to form a tether, with a flat smooth layer of uncross-linked photoresist material as a support to be removed during development, thus leaving another part of the first photoresist free to move, creating the active structure.

The method may comprise a step of forming conductive pathways or interfaces within the printed structures. In one example, a polymer coated metal or other conductive foil can then be bound to the polymer photoresist, and left in place. In other examples, conducting polymers, polymer coated foils or conductive photoresists or conductive inks may be interfaced with one or more layer of photoresist and left in place. The combination of the active structures with conductive elements as described, provides the ability to rapidly print low cost microsensors. The conductive pathways could comprise non-metal materials such as conducting polymers, semi-conductor material, and/or carbon nanotube loaded photoresists and/or other polymers.

The method may comprise the ability to deposit transducer materials as part of the microstructure, an example being the deposition of polyvinylidene difluoride, a piezoelectric transducer material, or other material that converts mechanical energy to electric energy, thus forming the ability to rapidly print microstructures such as energy harvesters.

The method may comprise the ability to combine active structures or microsensors with said formed transducer combinations, thus forming the ability to rapidly print self-powered sensors.

The method may comprise the ability to combine active structures with surface functionalisation, thus forming the ability to rapidly print microsensors for chemical detection for example.

The method may comprise one or more steps of forming a curved structure, such as a lens, or a lens array for example. This may be achieved by exposing the area around the lens (the negative lens space), then heating to cure, which sets the cross-linked material, while during the same process, heating the uncross-linked photoresist, which melts and reflows, using surface tension to form hemispherical structures, which may then be re-exposed (the inverse of the original negative space) and cured to form hardened lenses. For increased optical transparency, especially where solvent resistance is not required, the lens structures may remain unexposed to UV and hardened thermally.

According to a further aspect of the disclosure there is provided an article manufactured using the apparatus of any of the above aspects of the disclosure.

The article may be any one or more of:
a) unpatterned encapsulation or wafer bonding;
b) a free-standing structure;
c) a multilayer structure;
d) an aligned multilayer structure;
e) a substrate bound structure that can be either single or multilayer, aligned or not;
f) an active structure formed by the combination of partly bound and partly free-standing structures. Such an active structure may thus include a part or region that can move relative to another;
g) a structure that includes conductive elements;
h) an active structure that includes conductive elements.
i) a structure that contains transducer elements;
j) an active structure formed with the combination of transducer and conductive elements.

Further examples of such articles, as could be produced by the apparatus and method of the above statements, include the unpatterned encapsulation of electronics such as antennae, circuit boards, or electronic microcomponents.

Examples of single layer free-standing micro-componentry include articles such as miniature gears, cog wheels, springs, clips, lens holders, and stencils.

Examples of substrate bound structures include microstructured templates for precision stamps, electroplating, injection moulding, embossing, and soft lithography.

Examples of multilayer microstructures including hydrophobic surfaces, “gecko feet” type surfaces which may be used for precision robotics; or microfluidic chips.

Examples of active structures include cantilevers, plates, bridges, and membranes which are formed by selectively bonding part of a first photoresist to another photoresist to form a tether, while leaving part of the first photoresist free to move. Such active structures may comprise springs which are the basic components of MEMS springs, from which microsensors can be fabricated when combined with conductive and/or piezoelectric materials.

Further examples of such active structures include vibrational energy harvesters, which are micropillars acting as springs, combined with piezoelectric materials to convert vibrational energy to electric energy.

Examples of microsensors combined with vibrational energy harvesters include self-powered miniature sensors, as could be used for internet of things type hardware.

Further aspects of the disclosure, which should be considered in all its novel aspects, will become apparent from the following description.

### DESCRIPTION OF THE DRAWINGS

A number of embodiments of the disclosure will now be described by way of example with reference to the drawings in which:

FIGS. 1a and 1b are schematic side views of two variants of a dryfilm photoresist whilst FIG. 1c is schematic side view of a photoresist cartridge, in accordance with aspects of the present disclosure;

FIG. 2 is a schematic view of a first embodiment of an apparatus configured to manufacture an article using, in this example, a dry film photoresist, in accordance with the present disclosure;

FIG. 3 is a schematic view of a second embodiment of an apparatus configured to manufacture an article using a dry film photoresist, in accordance with the present disclosure;

FIG. 4 is a schematic view of a third embodiment of an apparatus configured to manufacture an article using a dry film photoresist, in accordance with the present disclosure;

FIG. 5 is a schematic enlarged view of part of the apparatus of any of FIGS. 2 to 4 using a collimated light source;

FIG. 6 is a schematic showing steps of manufacturing an article using a single layer of dry film photoresist, in accordance with the disclosure;

FIG. 7 is schematic showing steps of a method of manufacturing an article using a dry film photoresist, in accordance with the present disclosure;

FIG. 8 is a schematic of a second embodiment of an apparatus in accordance with one or more aspects of the present disclosure;

FIG. 9 is an enlarged view of a feed mechanism of the apparatus of FIG. 8;

FIGS. 10 to 15 are various views of the second embodiment of the apparatus of FIGS. 8 and 9;

FIG. 16 is an enlarged view of part of the apparatus of FIGS. 8 to 15;

FIG. 17 is an enlarged view of part of the feed mechanism of the apparatus of FIGS. 8 to 16;

FIG. 18 is an enlarged view of a printing platform and heating bed of the apparatus of FIGS. 8 to 17;

FIG. 19 is an enlarged view from one end of the apparatus of FIGS. 8 to 18;

FIG. 20 is an enlarged view from the side of the apparatus of FIGS. 8 to 19;

FIGS. 21 to 23 are further views of the apparatus of FIGS. 8 to 20;

FIG. 24 is an enlarged view from another end of the apparatus of FIGS. 8 to 23;

FIGS. 25 and 26 are side views of the apparatus of FIGS. 8 to 24 with the clamp in a raised condition;

FIG. 27 is an end view of the apparatus of FIGS. 8 to 25;

FIG. 28 is another enlarged view from one end of the apparatus of FIGS. 8 to 27;

FIG. 29 is a side view of the apparatus of FIGS. 8 to 28 showing the exposure system and heater in a raised condition;

FIG. 30 is a side view of the apparatus of FIGS. 8 to 29 showing the exposure system and heater in a lowered condition;

FIG. 31 is an enlarged perspective view of the projector lens, laminator roller and cutter of the apparatus of FIGS. 8 to 30;

FIG. 32 is a schematic side view of a roll of photoresist material;

FIG. 33 is a schematic side view of radiation from a radiation source incident on a photoresist;

FIG. 34 is a schematic side view of a number of exposed layers of photoresist, each with a defined area from a pattern, with the layers laminated in a stack;

FIG. 35) to c) show successive steps of processing of the stack of photoresists of FIG. 27;

FIG. 36 show examples of a photoresist that has been applied to non-flat surfaces;

FIG. 37 shows a photoresist that has been metallised on one side;

FIG. 38 shows processing steps whereby a photoresist comprises an embedded electrical conductor;

FIGS. 39 to 56 are examples of structures/articles/products produced in accordance with the Examples included in this disclosure.

### DETAILED DESCRIPTION OF SPECIFIC EMBODIMENTS

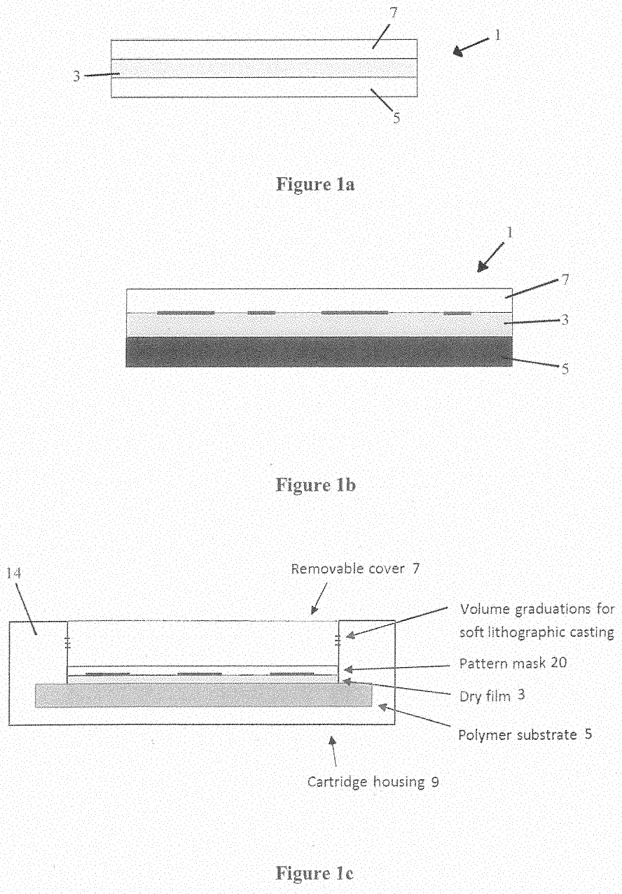

With reference to FIG. 1a, a dry film photoresist P comprises a layer of photoresist material 3 sandwiched between two carrier/cover sheets comprising a base sheet 5 and a protective sheet 7. The base sheet 5 may be considered to be a substrate in the following description.

An example of such a dry film photoresist P example as described in patent application US2006/0257785, the entire contents of which are incorporated herein by reference. An example of such a dry film photoresist is made and sold by DJ MicroLaminates (formerly known as DJ DevCorp), under the brand name ADEX®. Other examples of such dry film resists include the TMMF S 200 series (Tokyo Ohka Kyoto Co. Ltd.), DFR XP SU-8 3000 (Nippon Kayaku), DFR DF-1000, DF-2000 and DF-3000 series (Engineered Materials Systems), Ordyl SY DFR, or any series of these or other dry film resists. Other non-dry photoresists may also be used.

Examples of liquid resists include Microchem SU-8 (the industry standard negative thick liquid resist) or Gersteltec GM1000 series, thin (approximately 5 micrometres or less) photoresists include the AZ series produced by Merck Performance Materials GmbH, Shin-Etsu SIPR series and Nagase NR2000 series.

For a single layer print, a pre-coated cartridge of any of these photoresists may be used.

For multilayer structures it may be possible to squeegee successive layers of the resists, however, would require solvent removal before exposure.

With reference to FIG. 1b, the base sheet 5 of the photoresist P may comprise a UV blocking and/or antireflective carrier sheet. The protective sheet 7 may comprise a patterned top sheet.

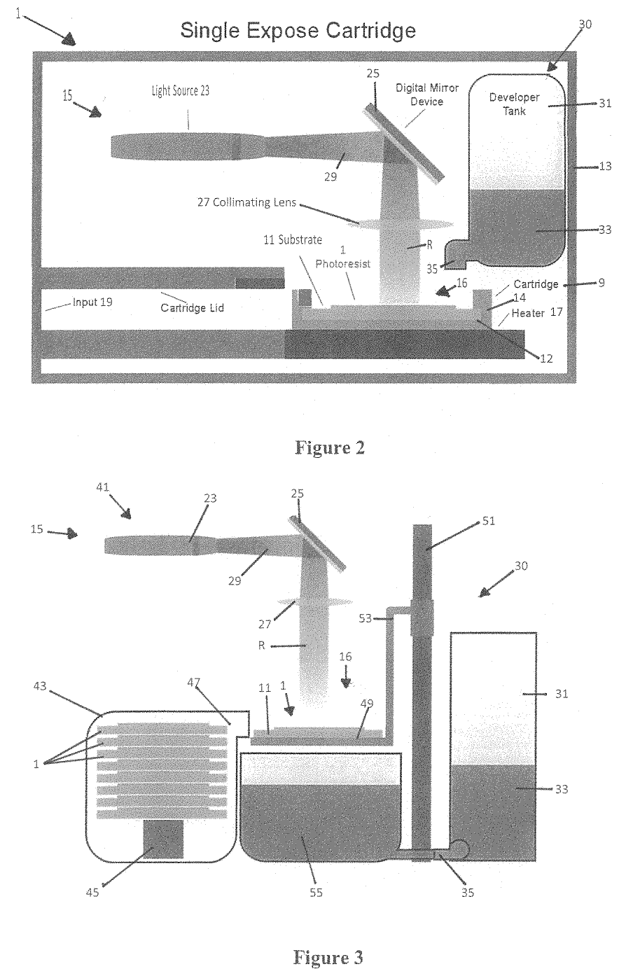

With reference to FIGS. 1c and 2, the photoresist P may comprise part of a photoresist cartridge 9 comprising a rigid substrate to which the base sheet 5 of the photoresist P is laminated. The substrate in this example comprises a cartridge base plate 12 and an upstanding peripheral wall 14, the photoresist P being contained within, and below, the wall 14. In this example, the cover sheet 7 comprises a pattern mask 20.

With reference to FIGS. 2, 5 and 6, an apparatus 1 is configured to manufacture an article using a dry film photoresist P of the type described above, which may or may not be part of a cartridge 9. The apparatus 1 comprises:
a housing 13 configured to receive the dry film photoresist P and locate the photoresist P in an operational position 16 in the housing 13;
an exposure system 15 configured to emit radiation R which is incident on the dry film photoresist material when in the operational position, to induce a change in one or more properties of the area(s) of the photoresist material exposed to the radiation; and
a heater 17 configured to subsequently heat and cure the dry film photoresist P to cross link the photoresist material 3 to the substrate 5. The housing 13 is configured to be radiation excluding, and may be UV excluding, at least to the extent that external radiation is sufficiently excluded from the housing 13 to prevent, or minimise polymerisation of the photoresist, at least when the dry film photoresist P is present, and further wherein the housing 13 is a clean housing configured to prevent contamination from entering the housing 13.

In this example the housing 13 comprises a cartridge inlet 19 configured to receive a photoresist cartridge 9. The cartridge 9 may be pushed into the housing 13, or the housing may be provided with a feed device configured to feed/drive the cartridge 9 into the housing 13 automatically. The cartridge 9 is inserted into the housing 13 until it reaches an operational position, generally indicated 16. An end stop or the like, could be provided to prevent over-insertion of the cartridge 9. A feedback mechanism could be provided to indicate that the cartridge 9 is in the correct position. For example the feedback mechanism could generate a noise, vibration or emit a light to indicate the correct position of the cartridge 9.

In this example the exposure system 15 comprises a light source 23, and two light manipulator devices in the form of an inclined digital mirror 25 and a collimating lens 27. The arrangement is such that light emitted from light source 23 follows a light path 29 which bends through 90° before being incident on the photoresist P. The collimating lens 27 helps minimise unwanted scattering of light within the housing 13.

The heater 17 in this example comprises a heater plate on which the cartridge 9 rests when in the operational position 16.

The apparatus 1 further comprises a developer unit 30 comprising a developer storage tank 31 in which a volume of developer fluid 33 is stored. In this example, the developer unit 30 is located inside the housing 13. In other examples the developer unit 30 could be separate from apparatus 1. The developer fluid 33 is dispensed from the tank 31 via a dispenser outlet 35 which may comprise an outlet pipe configured to simply drop developer fluid onto the cartridge 9, or may comprise a nozzle configured to generate a spray or mist of developer fluid 9. In other examples, development could be carried out within a subunit of the housing 13, such as the cartridge itself, or in a removable developer unit removeably mounted on the housing 13. The cartridge development can be used to protect the user from contact with the developer solvent. Development can make use of hot water which can be heated by heater 17, or by an external heat source, such as a microwave source. A bath, mist or spray system may be used, with or without developer fluid recirculation.

With additional reference to FIG. 5, the apparatus 1 or the cartridge 9 is provided with a patterning system 20 configured to form a pattern on the photoresist material 3 such that a region or regions of the photoresist material 3 is/are exposed to light from the light source 23. The patterning system 20 in this example comprises a photomask placed on top of the photoresist P. That exposure to light through the photomask 1 liberates the photo-initiator in the photoresist material 3 to form the desired pattern on the photoresist material and to allow some of the photoresist material 3 to be removed using developer fluid 33 from tank 31. Prior to development, but after exposure, the cartridge 9 is heated by the heater 17 to cure the photoresist material to cross link it to the cartridge substrate 11. After a suitable cool down period, developer fluid 33 is dispensed from tank 31 onto the cartridge 9, within the cartridge wall 14. The cartridge base and wall 14 form a bath of developer fluid in which the photoresist P sits. The developer fluid 33 causes the desired parts of the photoresist material 3 to be removed. The remaining photoresist material may then be baked, by reactivating the heater 17 for a predetermined duration and a temperature.

Referring to FIG. 3, a further apparatus 41 comprises similar features to those of apparatus 1. Like references have been used for like features. In this example, a photoresist storage device 43 is provided, removeably mounted in housing 13. A plurality of photoresists P are in this example stacked in the device 43 on a height adjustable rack 45. The rack 45 is configured to raise the uppermost photoresist P to a position aligned with the operational position in the housing 13 and to deliver that uppermost photoresist P to the operational position via a compartment outlet 47. The operational position in this example is defined by a platform 49 in the housing 13, which is movably mounted on a post or rail 51 via an arm 53 so that the platform 49 and photoresist P can be moved up and down within the housing 13. The exposure system 15 is as described above. In this example, the developer storage tank 31 feeds developer fluid 33 to a developer bath 55 directly below the platform 49. The platform 49 can be lowered into the bath 55 to develop the photoresist P, and then raised out of the bath 55 once developed. Raising and lowering the platform 49 also raised the photoresist P towards and away from the collimating lens. In this example, the heater 17 is in the form of an oven which heats the interior of the housing 13, at least in the region of the platform 49 and photoresist P. Apparatus 41 therefore provides batch processing of multiple photoresists P, where the batch processing may be fully or partially automated.

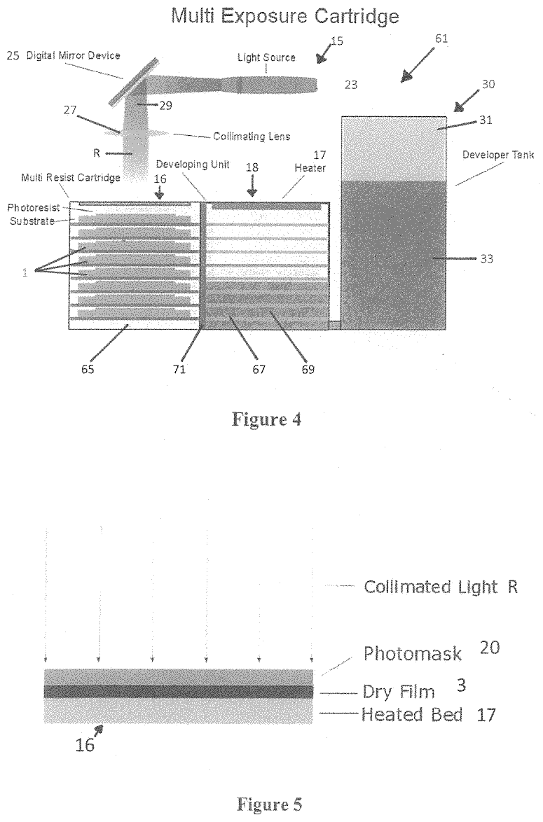

Referring to FIG. 4, a further apparatus 61 comprises similar features to those of apparatus 41. Like references have been used for like features. In this example, photoresist storage device 43 is again provided in housing 13. A plurality of photoresists P are stacked in the device 43 on rack 65. The rack 65 is configured to transfer each photoresist P laterally across into a second rack 67. The second rack 67 is contained within a developer bath 69, with a movable closure 71 located between the two racks 65, 67, and movable to an open position to allow a photoresist P on rack 65 to be transferred to second rack 67, and to subsequently close to form a sealed side wall of bath 69. In this example apparatus 61 provides a first operational position 16 for each photoresist P in rack 65, and a second operational position 18 for each photoresist P in second rack 67. The uppermost photoresist P in rack 65 is exposed to radiation from exposure source 23. Once exposed, movable closure 71 opens, and the photoresist P that has been exposed is transferred into second rack 67. The process repeats for all of the photoresists P in rack 65, which are sequentially exposed to exposure source 23. Once all of the exposed photoresists P have been transferred to second rack 67, the closure 71 closes to form the developer bath 69 which is filled with developer fluid 33 from tank 31 to simultaneously develop all of the photoresists P in second rack 67. In this example heater 17 comprises a heater plate located at the top of second rack 67.

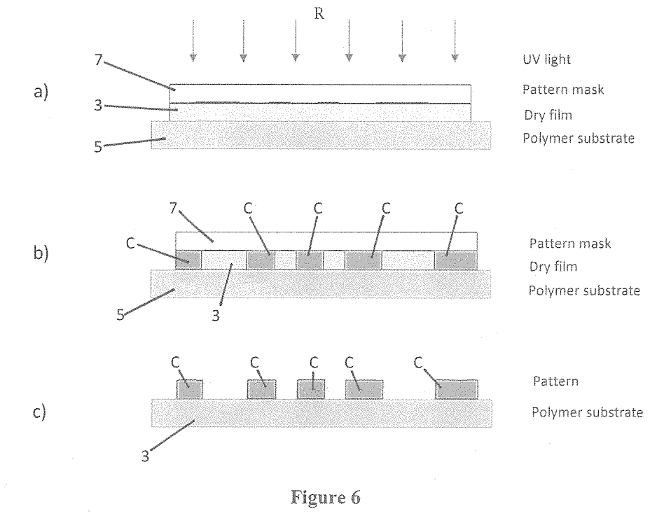

Referring to FIG. 6, apparatus 1, 41 and 61, is configured to be able to process a single photoresist P. In this example, the photoresist P is provided with a photomask 20 which may comprise the upper protective sheet 7 of the photoresist P or may comprise a separate component. The photoresist material 3 is laminated or placed on base sheet 5 comprising a polymer substrate in this example.

During step a) the photoresist P is first exposed to radiation R from the exposure source. In step b), once exposed, the heater 17 is activated to cure the photoresist material 3 so as to crosslink the regions C of the photoresist P that were exposed to the radiation R. The photomask 20 can remain in place during curing.

Once cured, the photomask 20 may or may not be removed, with the cross-linked regions C of photoresist material 3 cured to the base layer 5 in the desired pattern.

In step c), the photoresist P is developed using a developer bath or spray system, as described above. Development removes the non-crosslinked photoresist material and leaves an article being a 3D structure formed from multiple layers of photoresist material.

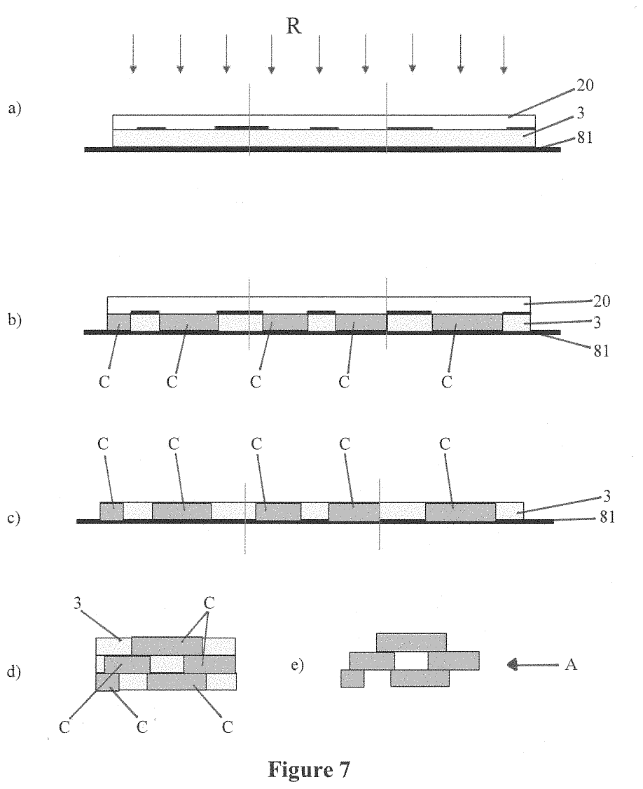

Referring to FIG. 7, a further apparatus, which may have any of the features discussed above with respect to apparatus 1, 41 and 61, is configured to be able to process multiple photoresists P simultaneously in order to be able to subsequently form an article from stacking or layering multiple photoresists P. In this example, the apparatus is configured such that multiple photoresists P, or a single photoresist P provided with multiple photomasks 20, can simultaneously be located in the operational position so as to be simultaneously exposed to radiation from the exposure system 15. In this example, the photoresists P are each provided with a photomask 20 which may comprise the upper protective sheet 7 of the photoresist P or may comprise a separate component. The base sheet 5 of each photoresist P is laminated or placed on a UV blocking substrate 81 in this example.

Once exposed during step a), the heater 17 is activated in step b) to cure the photoresists P simultaneously so as to crosslink the regions of each photoresist P that were exposed to the exposure source. The photomask 20 can remain in place during curing.

Once cured, the photomask 20 is removed in step c) and the multiple photoresists P are recombined in step d) by stacking or layering the photoresists P together, after removal of the upper protective sheet 7 (if not the photomask 20) and the lower UV blocking substrate 81. This recombining process may be manual, or may be automated within the apparatus 1, using appropriate actuators and photoresist handling mechanisms.

Once recombined, the stacked or layered photoresists P are simultaneously developed in step e) using a developer bath or spray system as described above. Development may or may not take place whilst the photoresist P is in the cartridge. Development removes the non-crosslinked photoresist material from the base layer 5 and leaves an article being a 3D structure, an example of which is shown in FIG. 7. As can be seen, the 3D structure is non-uniform and can include relatively complex features such as undercuts and/or internal, closed cavities. By stacking/layering multiple photoresists P in this way, relatively complex 3-D articles A can be produced. It is further envisaged that the photoresists P, or the substrates on which they are mounted, can have keying or locating features configured to engage together, or with corresponding formations on the apparatus, to correctly orientate and locate the multiple photoresists P together when stacked/layered. Alternatively or additionally, the apparatus may comprise one or more aligning/guiding features such as rails, lugs or projections that are arranged to correctly orientate the layers of photoresists P.

Such an apparatus uses the principle of having gained control of the prior deposited layers to use them, before development of the photoresist material, as a relatively flat, relatively smooth surface on to which to laminate subsequent layers without slumping between them.

In these examples, the housing 13 comprises a cuboidal box. The housing may comprise any self-contained, preferably portable, radiation blocking (in some examples UV blocking), clean container or box. In some examples, the housing 13 is shaped and dimensioned to be form a desktop unit. In one example, the dimensions of such a box are 60 cm by 40 cm by 75 cm with a weight of around 10 kg. Such a unit might be useful for prototyping or other lower resolution manufacture. In other examples, the housing 13 may be somewhat larger in order to be able to produce higher resolution articles. In any example, the housing 13 is such that it is considerably smaller than a traditional clean/yellow room, and is configured to be a unit contained in room of a building rather than itself being a room of a building. The housing 13 may therefore be relatively small and compact. The housing 13 may be configured to be freestanding.

An example of the apparatus is a prototyping photolithographic apparatus in a self-contained box, designed as a relatively low cost, relatively small footprint, relatively easy to use, relatively rapid and relatively safe alternative to replace basic conventional photolithographic processing. Typical prior art microfabrication processes can take hours to days to achieve. Examples of this disclosure enable a significant reduction in time spent on fabrication by automating fabrication processes, such that once set up, the apparatus operates semi or fully autonomously; as well as reducing the overall speed of the process, by containing a number of steps within the single apparatus.

The housing 13 takes place of the conventionally used yellow safe-light cleanroom, as the housing 13 itself is a UV excluding cleanroom, protected from ordinary room air. The housing 13 also takes the place of the complex and expensive setup conventionally used for photolithography, as the housing includes the UV exposure and heat cure sources necessary to liberate the photoinitiator and cross-link the photoresist material 3 to the substrate 5.

The apparatus may use any photoresist P that comprises photoresist material applied to a substrate. It may in some examples be preferable to use a dry film photoresist, and in some examples to use one or more Thick Dry Film photoresist Sheets (TDFS) of the type manufactured by DJMicroLaminates for example.

The apparatus patterns upon exposure to radiation from an appropriate energy source of the exposure system 15. The photoresist sheets 1 are preferably handled between disposable carrier sheets 5, 7. If the carrier sheets and/or cartridge are UV blocking, this facilitates easy handling of the photoresists P in a manner similar to a printer cartridge or the like, without requiring clean/yellow room conditions. The photoresist sheets 1 can be positive or negative toned, chemically amplified or not, image reversal or not. Alternative sources of photoresist such as spin-coatable, dip, spray, rollable, screen printable, slot die or doctor-bladed etc photoresists may also be used.

When used, the base sheet 5 and protective sheet 7, also known as photoresist carrier sheets, can remain in place to prevent particulates from reaching the photoresist itself, to control surface tension during processing and as a surface for direct patterning (avoiding the need for a separate photomask or the like).

As the housing 13 is radiation excluding, it also prevents radiation source exposure to the user.

The patterning can be from a photomask 20 as described above. This mask can be a high quality glass photomask, but any high contrast but transparent media may be used as a conformal print mask to improve resolution. Greyscale masks can be used. Alternative methods of patterning include maskless patterning methods which can use digital light processing (DLP) with digital micromirror devices (DMD) or laser based printing techniques such as those used with a laser printer, or for writing compact discs or digital video discs for example. A suitable projector or laser can be provided configured to automatically expose the photoresist in the desired pattern. The projector or laser may be operative according to a suitable electronic pattern file from an external data storage device, or generated electronically using the controller of the apparatus, or wirelessly from a remote computer or device.

The heater 17 could be, for example: an infrared heater, hotplate or heater base, or an oven. As the heater 17 is contained in the housing 13, it also prevents the user from direct contact with heat, eliminating a further hazard. The heater 17 may be sandwiched between plates of a photoresist support.

The apparatus 1 can be controlled using one or more manual or automated controllers, either by manual switched input, timers, electromechanical systems or using one or more microcontroller. The apparatus 1 can also be integrated with the internet of things, for example via a suitable Wi-Fi transceiver and controlling software/hardware in the apparatus 1.

Development could be carried out in the box, or within a subunit of the box, such as the cartridge itself. Development can be arranged to protect the user from contact with the developer solvent. Development can make use of hot water which can be heated from the box heat source, or external source, or a microwave source. A bath, mist or spray system may be used, with or without recirculation.

For wafer bonding or encapsulation, where antennae, circuit boards or micro-components are fully coated and flood exposed for protection, no patterning system is required. For positive toned resists, no heating system is required.

The housing 13 can be manufactured from a radiation, and preferably UV, blocking material such as custom Polycarbonate. The housing 13 may be manufactured using any one or more of: 3D printing; laser cutting or milling. The housing may be provided with a closure in the form of a door or the like to close the housing 13 when the photoresist P is in the operational position. The closure may be provided with an interlock in the form of an electronic or magnetic lock controlled by the controller to lock the closure when the photoresist P is in the operational position.

The UV radiation emitted by the exposure system may be from any of the following light sources: Fluorescent AC or DC; LED, laser. The exposure system may comprise a safety system configured such that UV radiation can only be emitted when the photoresist P is in the operational position and the housing 13 is in a closed condition, that is, the housing 13 is UV blocking. One or more sensors may be provided configured to generate signals indicative of these factors, the controller only activating the exposure system when the sensor(s) indicate that one or both conditions are fulfilled. The exposure system may include a cold start system configured to warm up the UV source prior to exposing the photoresist to UV radiation. A suitable shutter may be provided.

The heater 17 may comprise a 3D Printing Bed and associated heater driver.

The controller may comprise a microcontroller. One example is an Arduino microcontroller. The controller may comprise any one or more of the following features: timer, thermometer; thermocouple; IR noncontact; thermistor; light detector; LDR with filter. The controller may be internal of the housing 13, externally mounted on the housing 13, or in communication with components of the housing 13 via wired or wireless connection. One or more sensors may be provided to generate sensor signals indicative of one or more characteristics of the apparatus, the signals being processed by the controller.

The apparatus 1 power supply may include an AC-DC voltage converter, a transformer and may be internal or external of the housing 13. One or more relays may be provided between the controller, power supply and one or more components, such as the heater 17 for example.

The apparatus 1 may use dry film photoresists as previously described as the consumable in the manufacturing process. The dry film photoresists may be supplied as different thicknesses of photoresist between two removable carrier sheets. This in itself replaces several steps of conventional lithography.

The UV and heat sources may be controlled manually with timer and power switches. In a more automated apparatus, a microcontroller controls the exposure and cure profiles. In each case, the exposure and cure times depend on two primary input parameters: the thickness of the dry film resist sheet (which determines the exposure and curing time) and any substrate material (if present) (which determines the curing profile). The user can operate the apparatus by first inserting the cartridge, and inputting the parameters to select the appropriate length of UV exposure (which liberates the photoinitiator), then heat profile (which cross-links the photoresist and bonds to the substrate). Once inserted into the housing, the cartridge can sit in one operational position which alternately exposes then cures in situ. The entire photolithographic processing takes place in the housing, with carrier (or pattern) sheet and backing sheet (if used) in place. After cooling (which may be indicated by the box), the user removes the photoresist, discards the top carrier (pattern) sheet (or both sheets to speed development for freestanding structures) and is ready to develop.

The apparatus 1 may be configured for multiple applications, including, for example, production of electroforming moulds, microfluidic moulds including grey-scaled moulds, or free standing printed structures.

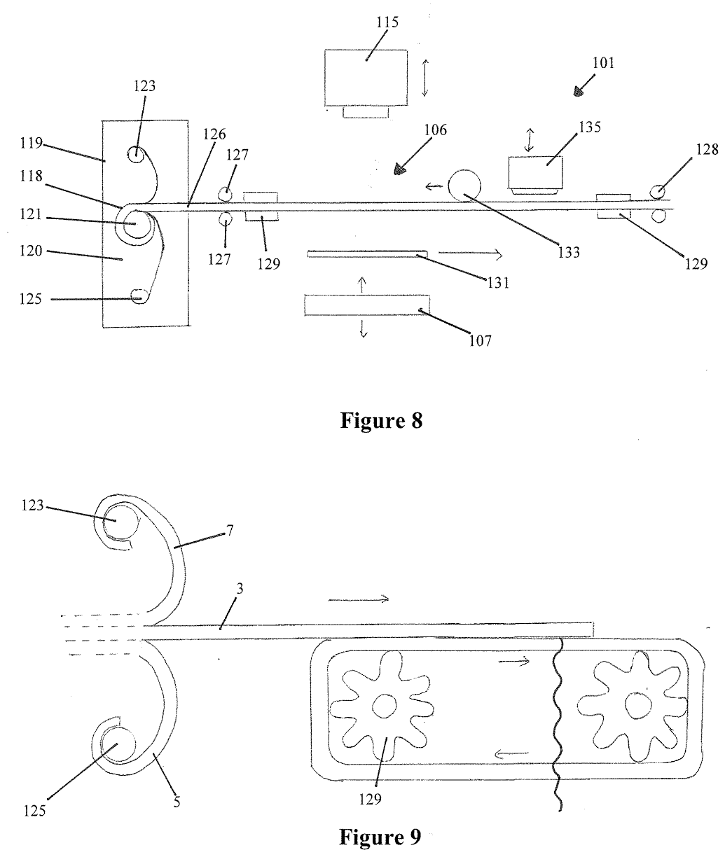

With reference to FIGS. 8 and 9, a further embodiment in accordance with the present disclosure comprises an apparatus 101 configured to manufacture an article using a dry film photoresist P of the type described above.

Apparatus 101 shows firstly a resist cartridge reel or roll 118, with top and bottom cover sheets removed to take-up rollers. The bare photo resist 3 is transferred to an operational position via belt drive, where it is held in place for image exposure. A moveable projector is used as an example of an exposure system for emitting suitable radiation source able to pattern each photoresist layer. The projector is moved up and down to facilitate exposure while also allowing room to manipulate the processing. A moveable shutter prevents unwanted incident light on previous layers located on the stage beneath. Once each photoresist layer is exposed, it is laminated to the previous photoresist layers in the assembly. After each layer is are exposed, a cutting tool separates the patterned area including a support frame, from the resist sheet or strip. The shutter is then moved back from the exposure area and the assembly is heated on the stage to cure and cross-link. The above components and process steps take place from within a clean, radiation excluding housing.

The apparatus 101 comprises:
a) a housing 103 configured to receive the dry film photoresist P and locate the photoresist P in an operational position 106 in the housing 13;
b) an exposure system 115 configured to emit radiation R which is incident on the dry film photoresist material when in the operational position 106, to induce a change in one or more properties of the area(s) of the photoresist material exposed to the radiation; and
c) a heater 107 configured to subsequently heat and cure the dry film photoresist P to cross link the photoresist material 3 to the substrate 5. The housing 13 is configured to be radiation excluding, and may be UV excluding, at least to the extent that external radiation is sufficiently excluded from the housing 13 to prevent, or minimise polymerisation, at least when the dry film photoresist P is present, and further wherein the housing 13 is a clean housing configured to prevent contamination from entering the housing 13.

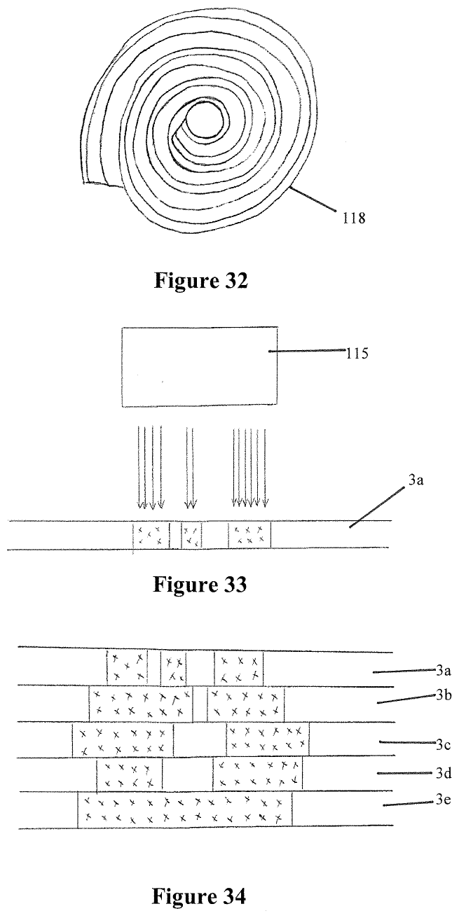

In this embodiment, the photoresist 3 is provided on a roll 118, shown schematically in FIG. 32. The end of the roll 118 of photoresist 3 is fed into an apparatus inlet 119, also shown in FIG. 17, which comprises a hollow inlet storage housing 120, which is radiation blocking, comprising three spaced apart rotating elements in the form of rollers 121, 123, 125. This inlet housing 120 may be configured as a removable cartridge which can be removably mounted on the apparatus 101. This cartridge may be radiation blocking so that the cartridge and photoresist roll can be easily transported.

The roll of photoresist is located on central roller 123. At least the outer rollers 123, 125 are driven so as to rotate, and in this example central roller 121 is also driven. During this rotation the outer cover sheets 5, 7 of the photoresist 3 are wound onto the respective outer rollers 123, 125. Continued rotation of the rollers 121, 123, 125 drives the photoresist 3 in a linear direction through an outlet 126 of the inlet housing 120 and into the apparatus 101, towards the operational position 106. This inlet arrangement facilitates a continuous, or at least relatively rapid, feeding of photoresist into the operational position 106, without any user intervention.

The photoresist 3 next passes between two spaced apart drive rollers 127 which sandwich the photoresist 3 and drive the photoresist 3 into operational position 106. The photoresist 3 passes across the operational position 106 and is fed into further drive rollers 128 which also sandwich the photoresist 3. The combination of rollers 127, 128 assist in maintaining the appropriate tension and alignment of the photoresist 3, and help prevent deflection of the photoresist 3 across the operational position 106.

The part of the photoresist 3 that is in the operational position 106 is then clamped at its opposed margins by clamping mechanism 129. Clamping mechanism includes a movable clamping plate 129C which is movable down into engagement with the photoresist 3. The clamping plate 129C has a central aperture 129D in which the photoresist is exposed. The central aperture 129D is sized to accommodate the size of article being produced.

The photoresist 3 may be supported during movement on one or more drive belts 122 which are driven by drive rollers 127 at one end, and supported by drive rollers 128 at an opposed end of the belts 122.

A radiation blocking device 131 is moved into, or may already be in, position underneath the clamped portion of the photoresist. In this example the radiation blocking device 131 is configured as a movable shutter which can be moved towards and away from the operational position 106.

With the blocking device 131 in position, the clamped portion of the photoresist is exposed to radiation emitted from a projector of the exposure system 115. The projector is configured to radiate the photoresist according to a desired pattern which may be programmed or loaded into a controller of the apparatus 101.

Once the photoresist has been exposed, the blocking device 131 is moved from the operational position 106 and heater 107 is moved into contact with the underside of the photoresist 3. The heater 107 in this example comprises part of a movable heater platform, stage or bed located in the operational position 106 beneath the clamped portion of the photoresist 3, and beneath the blocking device 131. The movable stage may be configured to move substantially perpendicularly towards and away from the photoresist, and the projector may be configured to move similarly. The movable heater stage and projector may be directly connected, or at least controlled to move simultaneously.

Once the heater 107 is in contact with the photoresist 3, a laminator 133 then laminates the clamped portion of photoresist 3 to the heater 107. Laminator 133 comprises a laminator roller 133A which can be heated if required. If a layer or layers of existing photoresist 3 is already located in position on the heater 107, the current portion of photoresist 3 is laminated to the existing layer(s).

Once laminated, a cutter 135 cuts the clamped part of the photoresist 3 from the remainder of the photoresist roll. In one example, the cutter 135 may comprise a heated blade 135A.

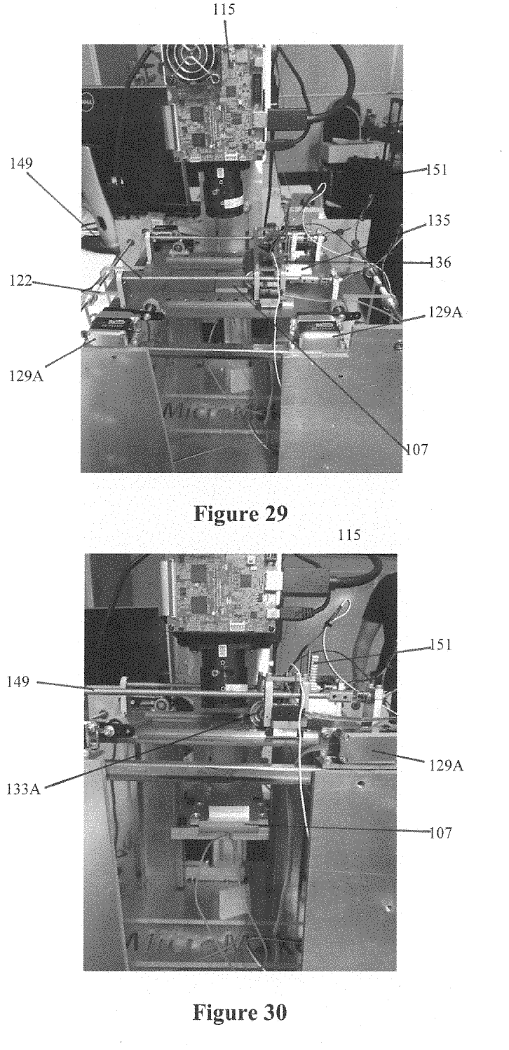

Both the laminator 133 and the cutter 135 may be movably mounted within the apparatus so as to be moveable to the desired position to cut and laminate the photoresist 3. Once laminated and cut, the laminator 133 and cutter 135 may be moved away from the photoresist 3 and away from the operational position 106. The heater stage or bed 107 then moves downwards, away from the operational position 106. As noted above, this movement may simultaneously move the projector 115 downwardly towards the operational position 106, for example from a position shown in FIG. 29 to a position shown in FIG. 30. This completes the pre-development processing of that portion of the photoresist 3. Subsequently, the next portion of photoresist at the cut and of the roll 118 is advanced into the operational position 106 and the above process repeated for each consecutive layer required to construct a multi-layer article.

It is envisaged that a surface of the radiation blocking device 131 could replace one of the cover sheets 5, 7 such that only one cover sheet 5, 7 is provided, and therefore a roller of the inlet 119 could be omitted.

Once the above process steps are complete, and all layers of photoresist required to form the article are exposed, the laminated stack of photoresist is developed, either in situ, or after the stack is moved to a developer unit.

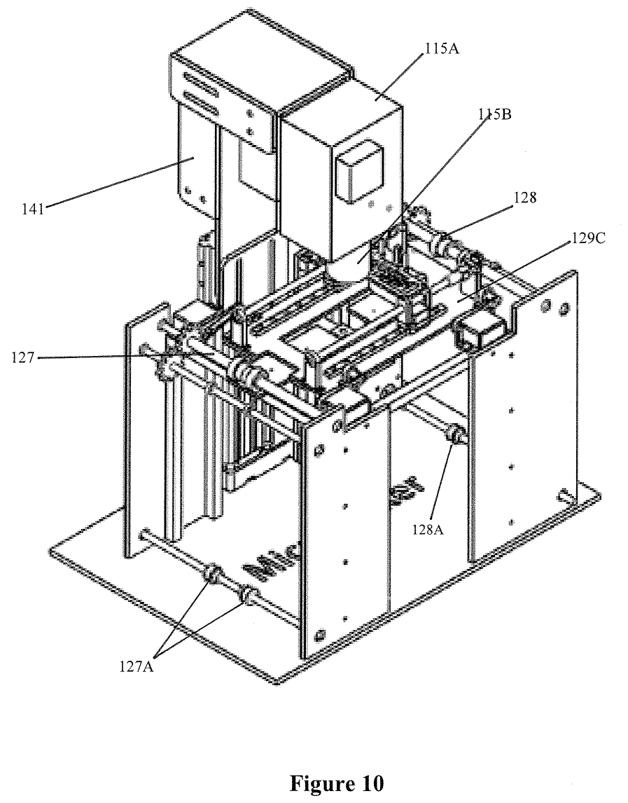

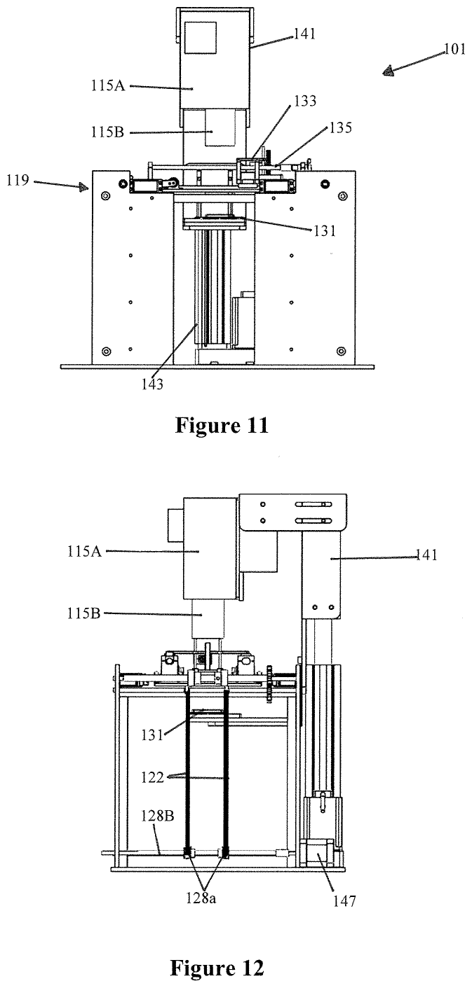

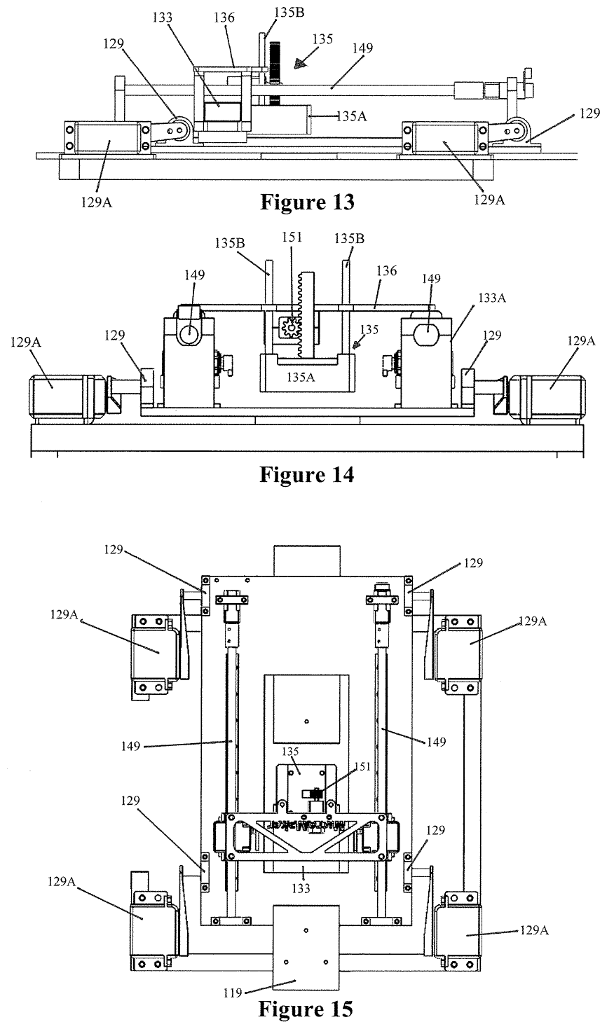

Referring now to FIGS. 10 to 17, further detail of the apparatus 101 is shown. In FIGS. 13 to 16, the belts 122 are not shown, for clarity.

In this example, the exposure system 115, and in particular projector 115A and any lens arrangement 115B, are mounted on, or comprise, a movable carriage 141 which is movably mounted on a vertically extending track 143. The heater bed 107 also comprises part of, or is mounted on, the carriage 141. The carriage 141 is configured to move along the track 143 to move the projector 115 and heater bed 107 towards and away from the operational position 106, as described above. The track 143 may for example comprise a toothed rail or similar which engages with a motor driven gear on the carriage 141. The carriage 141 and track 143 together comprise a form of linear actuator.

The drive belts 122 may extend horizontally across the apparatus 101 and then extend substantially vertically to further rollers 128A which may be driven via a drive motor 147 and drive shaft 128B located at or adjacent the base of the apparatus 101.

Referring to FIGS. 13 to 16, each clamp 129 comprises a clamp servo 129A configured to activate and deactivate the clamps 129. The laminator 133 comprises a lamination servo 133A and a lamination roller 133B configured to press the photoresist 3 onto the stack of photoresist layers below.

Both the laminator 133 and cutter 135 are mounted on a linear actuator, which in this example comprises a carriage 136 mounted on a pair of spaced apart lead screws 149 extending horizontally across the apparatus 101. Rotation of the lead screws 149 moves carriage 136, the laminator 133 and cutter 135 into and out of the required positions. In this example this movement is in a substantially horizontal direction across the apparatus 101, above the heater bed 107 and clamping plate 129C.

The cutter blade 135A in this example is configured as four blade portions arranged as an oblong when viewed from above, to define a central aperture, similar to a cookie cutter. The blade 135A is mounted on vertical rods 135B which are mounted on carriage 136 to enable the cutter blade 135A to move toward and away from the operational position 106, relative to the carriage 136. Another linear actuator, in this example provided as a rack and pinion 151, drive the movement of the cutter blade 135A relative to the carriage 136 toward and away from the operational position 106.

In all of the above examples, any of the linear actuators described could be replaced with alternative types of linear actuators. Such alternatives include any one or more hydraulic, pneumatic, geared, electromagnetic, or purely mechanical.

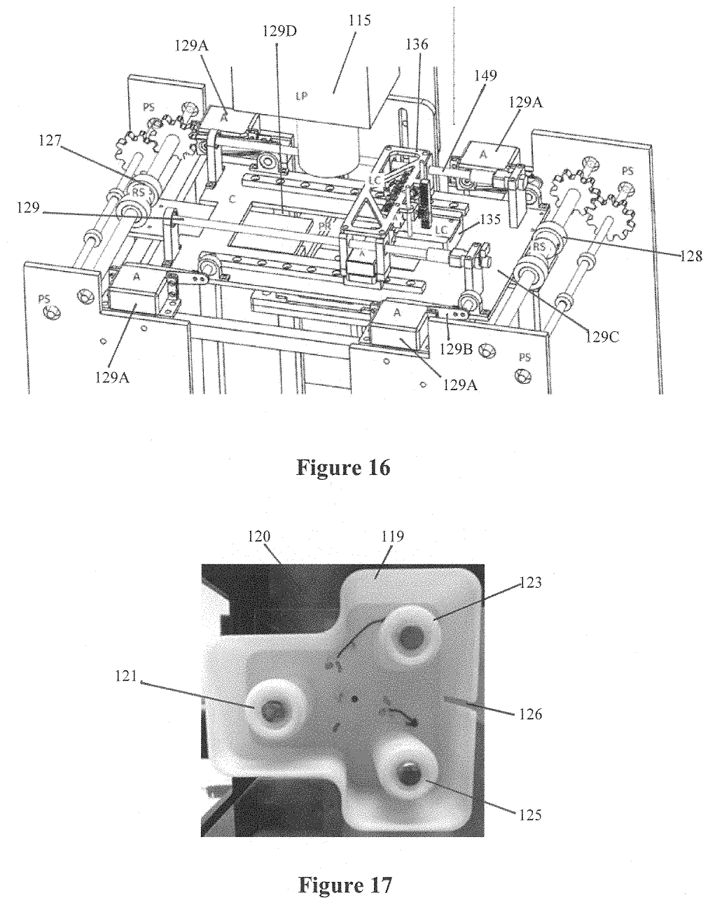

As can best be seen from FIG. 16, the apparatus 101 broadly comprises the following photoresist positioning and alignment features:
a) an inlet and storage arrangement configured to store a supply of photoresist;
b) a feed arrangement configured to feed the photoresist from the inlet into the operational position;
c) a drive arrangement, comprising a plurality of driving rotating elements, drive belts and guide/driven rotating elements; configured to move the photo resist into the operational position in the apparatus;
d) guide/alignment/locating rails or members configured to locate and align the photoresist in the operational position;
e) a retaining or clamping arrangement to temporarily fix the photoresist in the operational position;
f) a platform or bed on which the portion of the photoresist to be exposed rests when in the operational position;
g) a laminating arrangement configured to laminate the photoresist to the platform or bed, or to any existing layers of photoresist already on the platform or bed;
h) an exposing arrangement, comprising a projector or other exposure source, configured to radiate the laminated portion of photoresist;
i) a heating arrangement, which may be integral with the platform or bed, to cure the laminated portion of photoresist;
j) a cutting or separating arrangement to separate the laminated photoresist from the remainder of the supply of photoresist;
k) one or more actuator arrangements configured to move any one of: the platform or bed, the laminating arrangement, the exposing arrangement, the heating arrangement and/or the cutting or separating arrangement, into and out of the operational position.

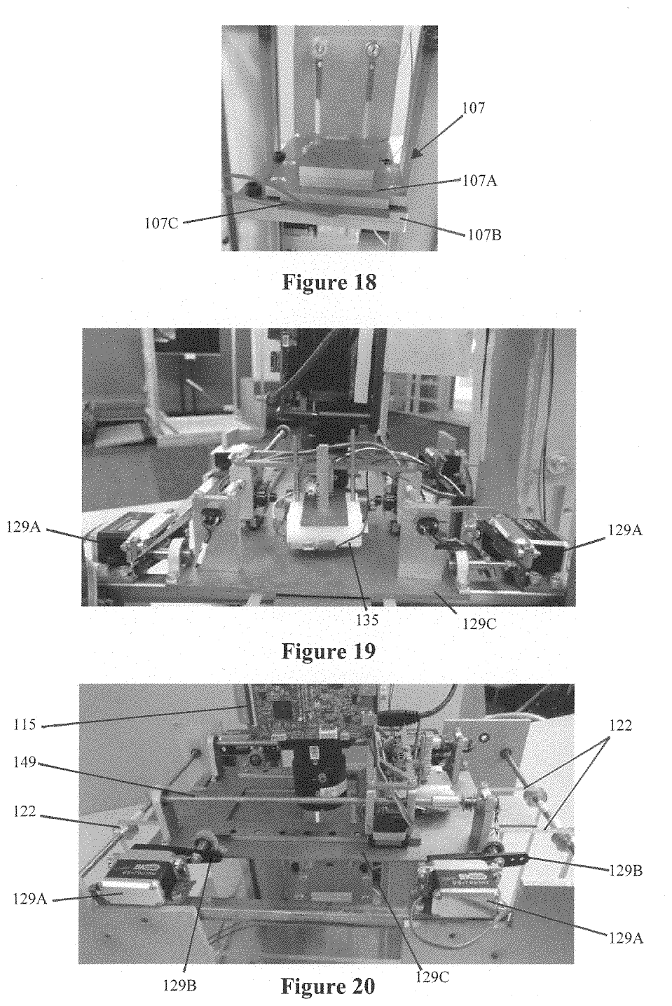

Referring to FIG. 18, an example heating platform or bed 107 is shown comprising a planar platform part 107A configured to support the photoresist when in the operational position 106, a base part 107B, and a heater part 107C sandwich between the platform and base parts 107A, C.

FIGS. 19 and 20 show detail of the apparatus 101 described above, with some parts removed for clarity.

FIGS. 19 and 28 is a view from one end of the apparatus 101 showing the linear actuators 129, carriage 136 and cutter 135. Cutter 135 is mounted on the rack of rack and pinion assembly 151 so as to be movable substantially vertically toward and away from operational position 106. Cutter 135 is embedded with Nichrome ribbon through which an electrical charge can be delivered such that the cutter 135 becomes sufficiently hot to cut through the photoresist material.

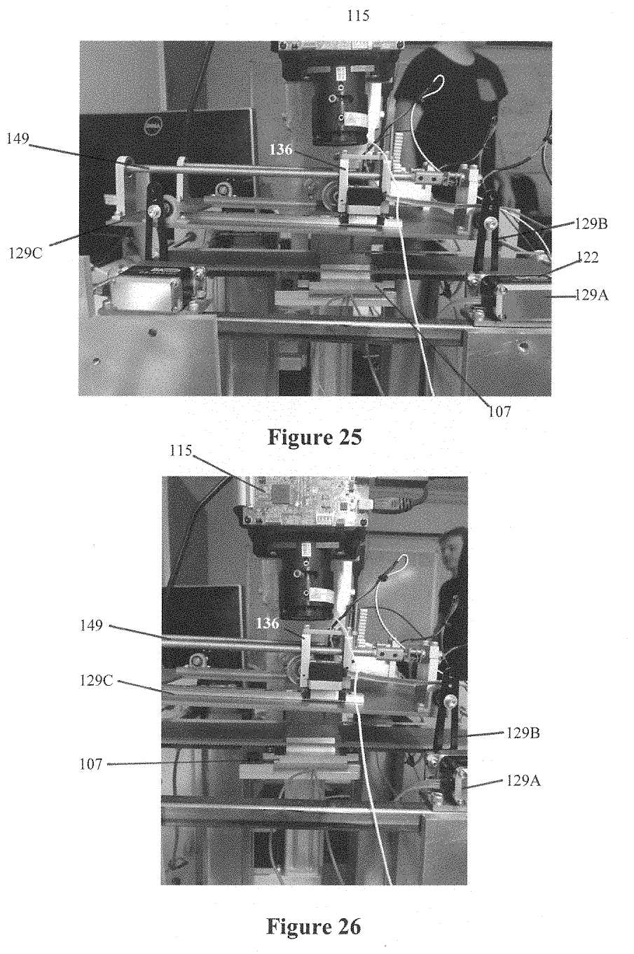

FIGS. 20, 25 and 26 are views from the side of apparatus 101 and show the projector lens 115B adjacent heater bed 107. In these figures, the carriage 136, laminator 133 and cutter 135 are in a non-operational position (and in FIGS. 25 and 26 the clamping plate 129C is in a raised, non-clamping position), so as not to impede exposure of the photoresist to radiation from the projector 115. The clamps 129 and clamp actuators 129A can also be seen. Each clamp 129 comprises a pivotable arm 129B rotatably mounted on clamping plate 129C. Rotation of each arm 129B by the clamp actuators 129A raises and lowers the clamping plate 129C so as to clamp down onto the photoresist. The photoresist strip, from the roll, is fed underneath the clamping plate 129C by the belts 122 which also extend underneath the clamping plate 129C.

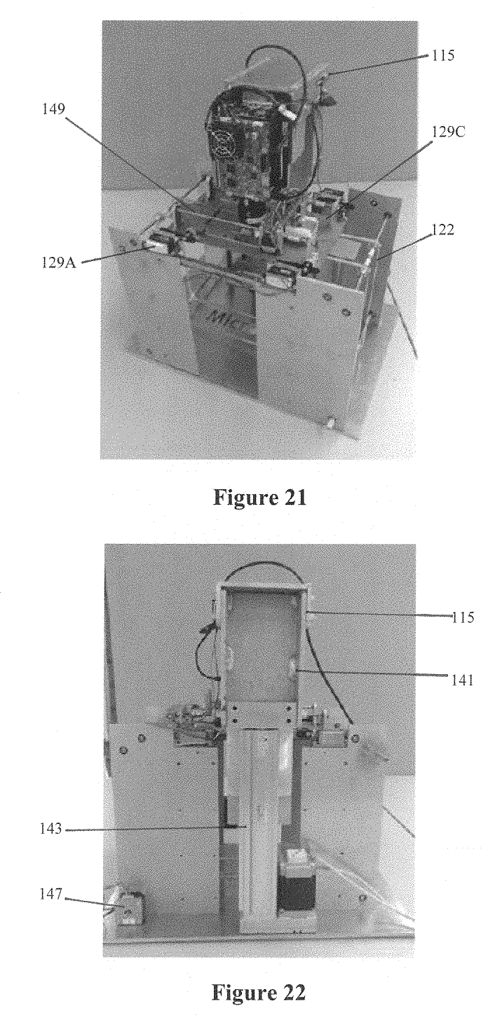

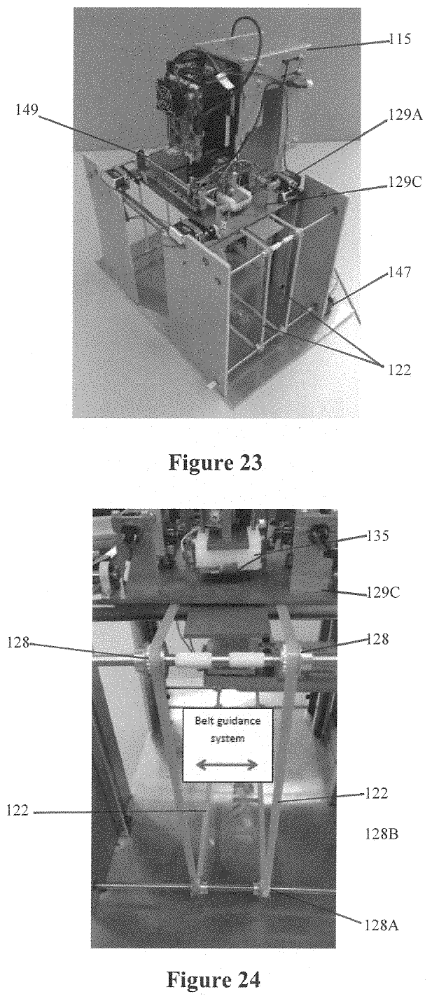

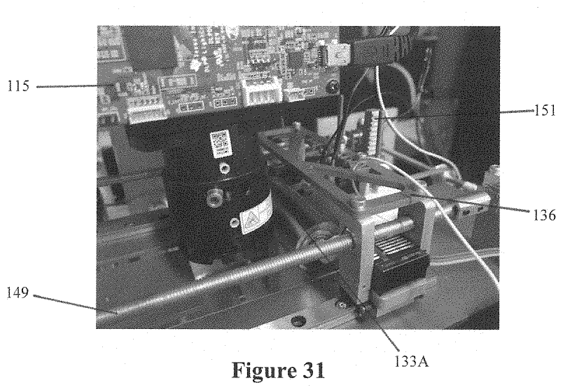

FIGS. 21 to 31 are further views of an example apparatus 101, with FIG. 22 being a rear view showing the rear of projector 115 and carriage 141, and track 143.

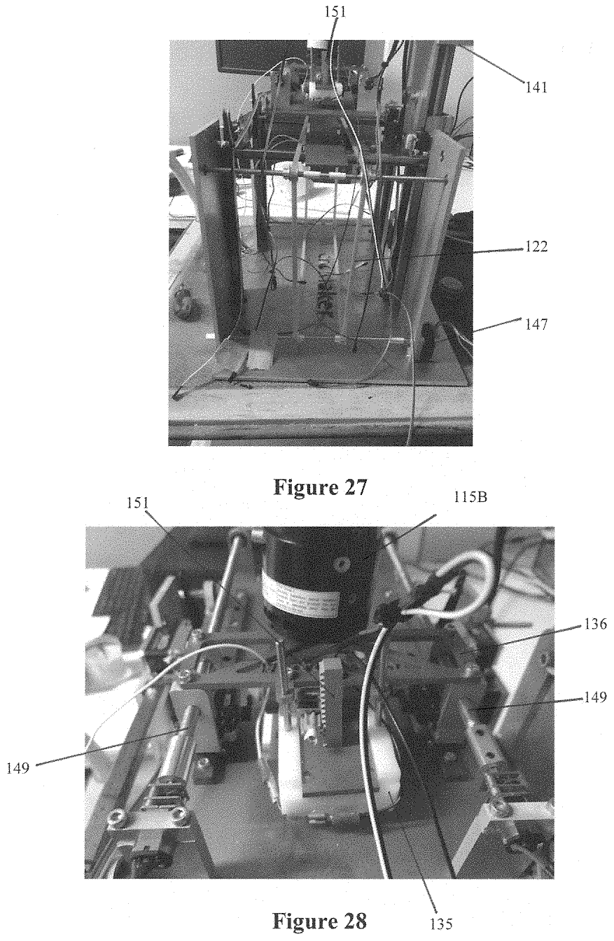

FIGS. 24 and 27 are enlarged views from one end of apparatus 101 and shows the routing of twin, parallel, laterally spaced drive belts 122 passing underneath the clamping plate 129C, around end rollers 128, vertically downwardly, before returning back underneath the apparatus 101. In this example the belts 122 are toothed belts and engage with teeth on rollers 128, and on lower rollers 128A. The lower rollers 128A are mounted on a drive shaft 128B which is driven by motor 147. Driving of the lower rollers 128A, 128 and 127 assists in maintaining the desired tension and alignment of the photoresist material 3.

The blocking device 131 prevents existing layers of photoresist on heater stage 107 from being exposed. Movement of the projector 115 away from the operational position allows space for exposure of the photoresist, and for the further processing steps.

It is also envisaged that any one or more of the rollers 121 to 128 could be driven or passive. For example, central feed roll roller 121 could be passive, with the outer cover sheet rollers 123, 125 being driven. The rollers may be driven from a single motor using a suitable drive transfer mechanism such as a belt or belts, or gears. The term ‘rotating element’ includes any rotating element, including for example, rollers and/or wheels and/or gears.

The projector 115 could be provided with additional guide rails or other supplementary supporting structure to assist in maintaining the correct position relative to the photoresist and operative position 106, and to minimise vibration during use.

The apparatus 106 may incorporate an integral controller or may be controlled via a separate controller.

The heater plate or bed 107 could be sprung, to bias the heater plate 107 into contact with the photoresist.

The outer, radiation blocking housing, which is not shown in some of the Figures discussed above, can be earthed.

In some examples the projector 115 is configured to project into an area approximately 10 mm by 20 mm. This area can be varied in accordance with the size of article to be produced.

In some examples, the primary components can be modular, in that a component is configured to be removably mounted to adjacent components so as the relative positions can be adjusted, and/or so that one component can be replaced with another. For example, the projector 115 can be removably/adjustably mounted on the carriage 141 so that a different projector or other type of exposure system can be used. Similarly the cutter/cutter blade 135A, and the laminator roller 133A could be removably/replaceably mounted. Likewise the heater plate 107.

The lead screws 149 could be located underneath the clamping plate 129C.

We now refer to FIG. 32 onwards, which schematically show photoresist processing steps according to various different examples.

In FIG. 33, the photoresist 3 which has been transferred to the operating position 106 is patterned by selective exposure to incident light from the radiation source 115. Upon exposure to suitable radiation, a catalyst is liberated in the areas defined with an x. This Figure illustrates a simple example of one layer 3a used to form a multilayer article.

FIG. 34 shows a successive number of exposed layers 3a-3e, each with a defined area from the pattern. These layers 3a-3e are each formed as per layer 3a, with the desired pattern, and then laminated together using laminator 133, forming a stack S, as described above.

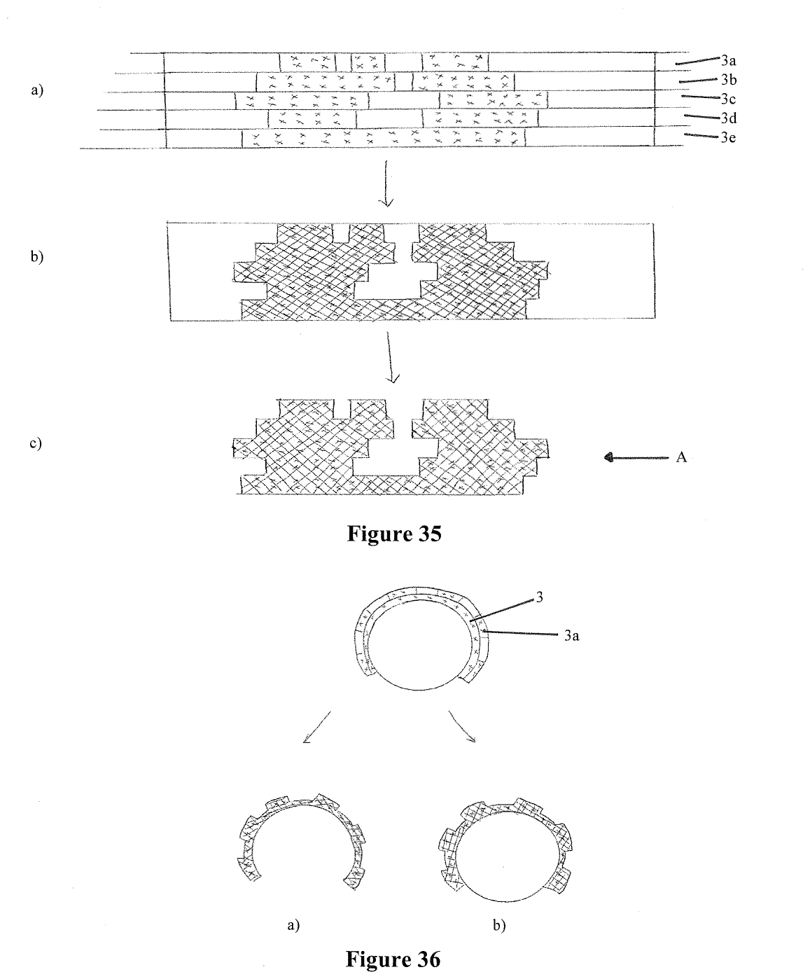

FIG. 35a shows the laminated stack S having been cut with the heated cutter 135, to prevent or minimise formation of dust fragments. In FIG. 35b the cut stack S is then heated to cure. The curing process cross-links the prepolymer resist (where exposed—as shown by an x), both across and between the layers, to form a single, integral cross-linked unit or article. The areas that have not been exposed are not able to cross-link, and act as a support material for the patterned structure. In FIG. 35c the uncross-linked support material is removed, for example by a solvent developer, or by being melted away to form the desired unit or article A.

In FIG. 7, the photoresist layer(s) have been applied to a non-flat surface, e.g. by use of a vacuum bag, to demonstrate the ability to produce curved surfaces. In FIG. 36a a freestanding structure is shown, whilst in FIG. 36b a bound structure is shown.

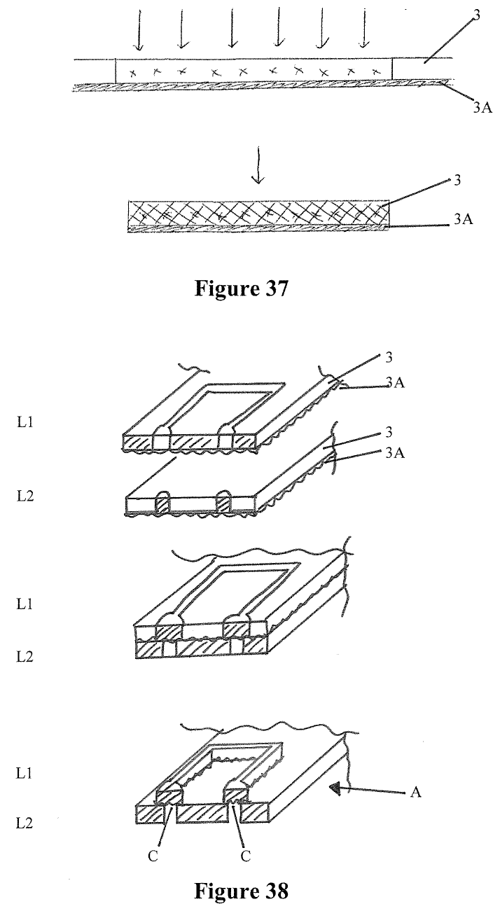

FIG. 37 shows the use of a photoresist sheet 3 that has been metallised 3A on one side, in this case by sputter coating with a mix of gold and palladium (commonly used for SEM image coating). The deposited metal layer 3A is made up of nanoparticles that adhere to the photoresist 3. Any metal nanoparticles that adhere to the unpatterned support layer are removed during develop, while the metal nanoparticles that adhere to the patterned structure remain in place.

Referring to FIG. 38, process steps are schematically shown for producing an article using a photoresist which includes one or more electrically conductive elements.

The starting material is a dry film photoresist 3 with a thin metal coating 3A on one side. As per FIG. 38a, two layers A, B of this material are patterned individually and then laminated together, as per FIG. 38b. They are then crosslinked. The laminated layers L1, L2 are subject to a first developing step in a solvent that will only remove the resin. The metal layer prevents unexposed resin on the bottom layer B from being developed. The exposed metal of layers A, B is then chemically etched—all metal that is not embedded is etched away. The third step is to develop again the now exposed resin—this will expose the metal conductors C as per FIG. 38c to produce a desired unit or article A. This process can be used to produce layered articles incorporating any desired number of conductive elements.

### EXAMPLE APPLICATIONS

The box may be used for, though not limited to the following applications:
For standard photolithography, cartridges may be conventional substrates such as silicon, glass or quartz wafers.
For electroforming moulds, an electrically conductive substrate (e.g. copper, or aluminium copper alloy or conductive polymer) is used.
For microfluidic moulds, the photoresist may be laminated onto machinable polymers such as PMMA or epoxy, and to increase adhesion, may come prelaminated with a base layer of photoresist for direct permanent bonding to the new pattern. These cartridges are designed with sidewalls to allow for casting elastomers such as polydimethylsiloxane, conventionally used to produce replica microfluidic devices.
For free standing printed structures, the photoresist are not laminated to a substrate.

### Modifications

To increase resolution, a patterned top sheet may replace the plain carrier sheet being the upper protective sheet 7. The patterned sheet is laminated and in direct contact with the photoresist. In this way, any resolution limiting diffraction from air gaps and loss of transmission through cover sheets is circumvented.

For free standing structures, a UV blocking backing sheet may replace, or be laminated to, the lower base sheet 5.

The apparatus could be further modified to:
Be self-cleaning, by use of an internal fan to generate a small positive pressure and changeable HEPA filters, with a counter to measure the number of cycles used or pressure sensor to detect timing for filter change. A spray down solvent cleaning system can also be included.
Control humidity by use of drying agents such as silica gel or a drying filter, with use of the inbuilt heat source and positive pressure to remove moist air.
Manufacture multilayer structures via an alignment system whereby multiple layers are simultaneously exposed, heat cured for the minimum amount of time only, until the latent image becomes visible, at which point the pattern itself can be used as an alignment tool without the need for reference markers. The layers can then be recombined by lamination after removing the carrier (pattern) sheets, then the thermal cure is completed allowing the layers to fully bond together. The layers can use plasma to assist bonding.
Incorporate materials such as conductive or piezoelectric inks or sheets, to form sensing/transducing structures.
Take design programming or from the internet of things.
Have the ability to scan in 2D or 3D to replicate structures.

The following examples are provided to illustrate certain particular features and/or embodiments. These examples should not be construed to limit the disclosure to the particular features or embodiments described.

The following examples describe structures fabricated in dry film resist using a pattern, radiation source and heat cure. The UV radiation source liberates a catalyst in the resist, which then cross-links together upon heating. Where multiple layers are used, they are combined by lamination. The cross-linking extends across the layers to form a single integral unit.

### Apparatus Example 1

This example describes a manually operated apparatus having both exposure and curing capabilities, designed for producing single layer planar structures in 100 μm thick SUEX. Other dry film photoresists may be used by adjusting the exposure and heating times. The apparatus has DC fluorescent UV light tubes of wavelength 365 nm set on 120 second timer for the exposure stage, and a heater with a toggleable heating element. The timer is set by an internal resistor and can be adjusted by replacing the resistor or using a variable resistor. The apparatus operates using the following steps:
1. A main switch is set into the timer position with the dry film photoresist placed in an operational position on top of the heating plate.
2. The apparatus is closed with a hinged door, to limit or prevent unwanted exposure from ambient ultraviolet radiation.
3. The timer button is pressed, illuminating red, and exposes the dry film photoresist to UV radiation from the exposure UV light source for 120 seconds.
4. The heater switch is then turned on, indicated by an internal red light. This is left on for 10 minutes to crosslink the exposed areas of photoresist.
5. The heater switch is then turned off and the apparatus left to cool for several minutes.
6. The article fabricated in dry film photoresist is then free to be removed and developed.

### Apparatus Example 2

A second example apparatus is configured for general purpose 3D prototyping using purpose machined photoresist cartridges, or a roll of photoresist.

The printed object is defined by the exposed area in each layer, successively built up over repeated layers to form a 3D object. The layer thickness is determined by the resist used, with resist sheets currently available in thicknesses from 5 μm through to 500 μm. Resolution in the Z axis is defined by this layer thickness. Resolution in the X and Y axes is defined by the pixel size of the pattern. A print voxel is therefore defined as the pattern pixel size times the resist sheet thickness.

For the projector used in this example (a Texas Instruments DLPDLCR4710EVM-G2 DLP projector with a 395 nm LED, and InfiniGage main body lens from Edmund optics), the pixel size is 4 μm. With the availability of increasingly high-resolution projectors, this resolution is improving. Reduction optics can further improve the resolution.

Permanent photoresists are by design, resistant to solvents, acids and bases; have a broad range of operational temperatures, typically −60 to 200° C.; and are flexible enough, with a Youngs modulus of ˜3 GPa, to allow active, or moving structures which form the basis of sensors.

This example apparatus has both exposure and curing capabilities, run by an Arduino microcontroller unit which times and sequences the exposure and heat profiles upon inputting the cartridge recipe. This prototyping apparatus operates using the following steps:
1. The apparatus is turned on via a main power button. This button, and any other buttons, may be separate to the controller, or displayed in a graphic user interface of the controller.
2. The photoresist cartridge or roll is loaded into the apparatus through a front entry slot.
3. The photoresist thickness is entered through the programmable LCD interface. The controller uses this single user input to determine and set the exposure time.
4. A start button is pressed to initiate the processing steps.
6. The photoresist carrier sheets are removed to two take up rollers.
7. The bare dry photoresist is moved to the operational position and the expose sequence initiated.
8. Each layer of photoresist is exposed by method of projection using a modified Texas Instruments DLPDLCR4710EVM-G2 DLP projector with a 395 nm LED and modified lens system, onto the photoresist film for the required time.
6. Following exposure, each layer of photoresist is laminated onto a stack, building up one layer for each pattern slice.
7. After each layer has been exposed and laminated, a heated ribbon wire slices the exposed assembly stack to define the print volume made up of exposed and unexposed areas.
8. The heat programme is initiated, which will ordinarily be 10 minutes on a 3D printer head bed. A heat indicator light will illuminate red during this time, changing to green when the assembly has cooled ready for removal.
7. After curing the article is removed from the operational position in the apparatus, ready for developing.
8. The printed article is developed by removing the uncrosslinked support material by dissolving it in a solvent such as propylene glycol monomethyl ether acetate (PGMEA). The crosslinked material is insoluble.

The following are examples of structures/articles/products produced according to aspects of this disclosure:

### Example 1

### Microstructures

These examples demonstrate semi-aligned multilayer textured surfaces, made up of two or more layers, which may include a substrate; which may be one or more layers of photoresist, or may be another material such as a polymer or paper, or may be substrateless (free-standing).

These examples can all be manufactured on a single layer device, such as described in Apparatus Example 1.

1a) Micro-Textured Surfaces

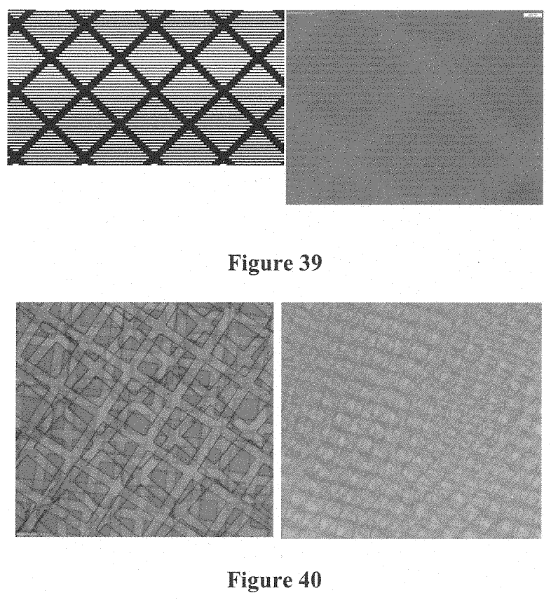

This example, with reference to FIG. 39, describes printing a “Shark's skin” type of geometric repeated pattern, which may be used for lubrication, antifouling surfaces, or for high surface area structures for catalysis, for example.

The example was patterned from a custom script designed in CleWin5, and printed in EMS DF 3550, a 50 μm thick negative dry resist, using a wholly exposed bottom layer as a substrate, with a top micropatterned layer.

The pattern is exposed with a print mask of 3386 dpi (7 μm) resolution (Agfa HNS polyester film output at 3386 dpi on a Heidelberg Herkules Pro imagesetter) and a 5 mW/cm² 365 nm collimated mercury arc lamp as radiation source.

After exposure, photoresist layers are laminated together at room temperature, then cured at 100° C. for 10 minutes to cross-link the structure.

Following curing, the structures were developed in PGMEA to remove uncrosslinked material.

1b) Microfilter

This example, with reference to FIG. 40, describes a filter made up of several layers of grids of 100 μm size, unaligned and oriented in different directions. The filter may be used for separating particles such as spores, or microfossils from soil, for example.

This example was patterned from a custom script designed in CleWin5, and printed in EMS DF 3550, a 50 μm thick negative dry resist, using a wholly exposed bottom layer as a substrate, with a top micropatterned layer.

The pattern is exposed with a print mask of 3386 dpi (7 μm) resolution (Agfa HNS polyester film output at 3386 dpi on a Heidelberg Herkules Pro imagesetter) and a 5 mW/cm² 365 nm collimated mercury arc lamp as radiation source.

After exposure, photoresist layers are laminated together at room temperature, then cured at 100° C. for 10 minutes to cross-link the structure.

Following curing, the structures were developed in PGMEA to remove uncrosslinked material.

1c) A Microwell Plate

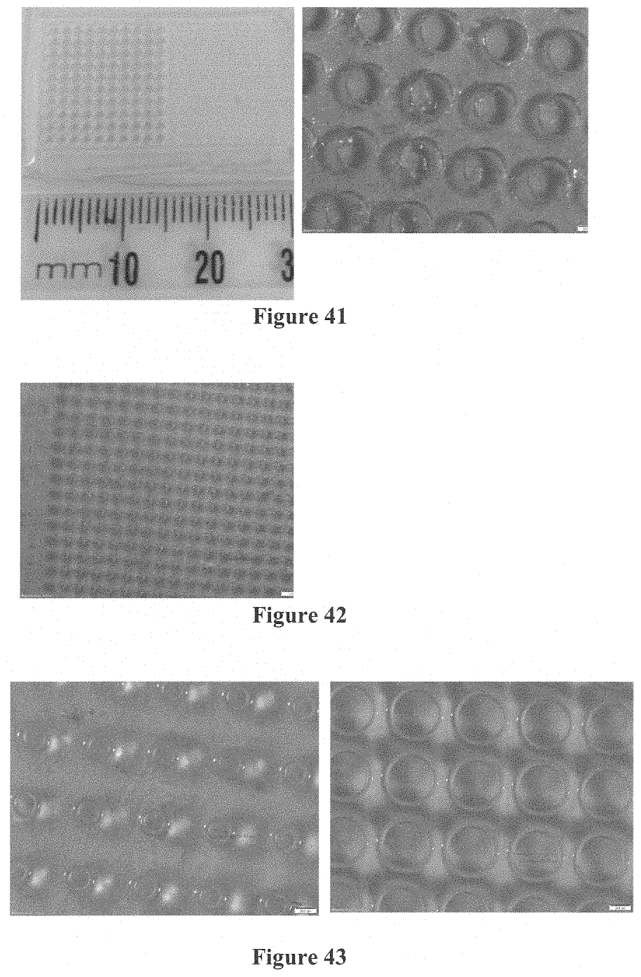

This, with reference to FIGS. 41 and 42, is an array of microwells made up of two layers including a substrate. The microwell plate is a standard tool in analytical research and clinical diagnostic testing laboratories, made up of a flat plate with multiple “wells” used as small test tubes to allow many reactions to be carried out in parallel from small samples.

The microwell was fabricated in SUEX D500, a 500 μm thick negative dry resist film, using a print mask of resolution 3386 dpi (7 μm) (Agfa HNS polyester film output at 3386 dpi on a Heidelberg Herkules Pro imagesetter) from a custom script designed in CleWin5, with a 5 mW/cm² collimated mercury arc lamp source and an exposure time of 2 minutes. An Electronic Microsystems hotplate was used to cure the structures for 10 minutes at 100° C. before removing uncrosslinked material by dissolving in PGMEA.

Two well plates are printed, one with a 1000 μm (1 mm) diameter, the other with a 500 μm (0.5 mm) diameter.

The inverse of the microwell structure, with reference to FIG. 43, was also printed as a micropillar relief mould for casting replicas, such as by the use of soft lithography with polydimethylsiloxane.

1d) Paper based Microstructure

Paper based microfluidics is finding favour for diagnostic testing due to the low cost and good wettability of paper.

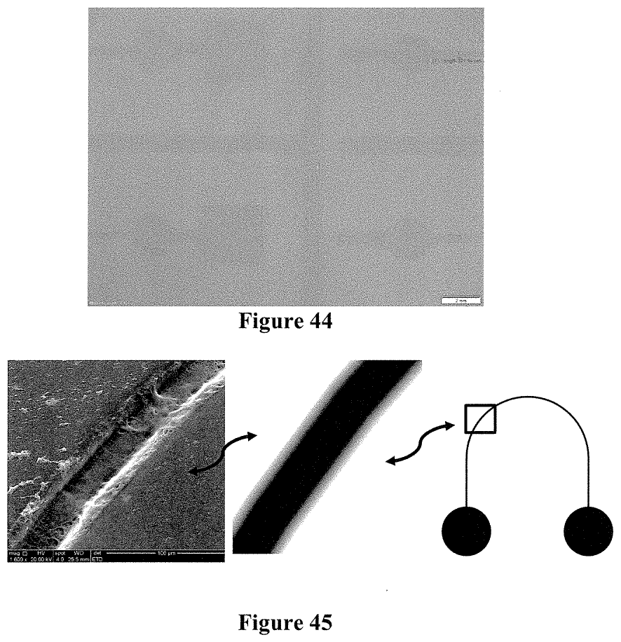

In this example, with reference to FIG. 44, a test structure was fabricated by removing the coversheets from 100 μm thick SUEX D100 and laminating to a sheet of Whatmans quantitative filter paper (grade 42) using a Sky 335R6 Pouch Laminator set at 67° C. and the lowest speed setting. The assembly is exposed with the paper as the base layer, using a glass chrome photomask with a custom designed pattern made in CleWin5, 365 nm UV fluorescent tubes with an exposure time of 2 minutes, then curing on a standard 3D printer hotplate at 100° C. for 10 minutes. After this, the uncrosslinked material was washed away in PGMEA leaving SUEX structures bound to a paper substrate.

### Example 2

### Greyscale Channel

Greyscale microfluidics channels have a use in that they can form rounded walls, so as to avoid reducing the laminar microfluidic flow as seen in conventional rectangular section channels with a 90° angle.

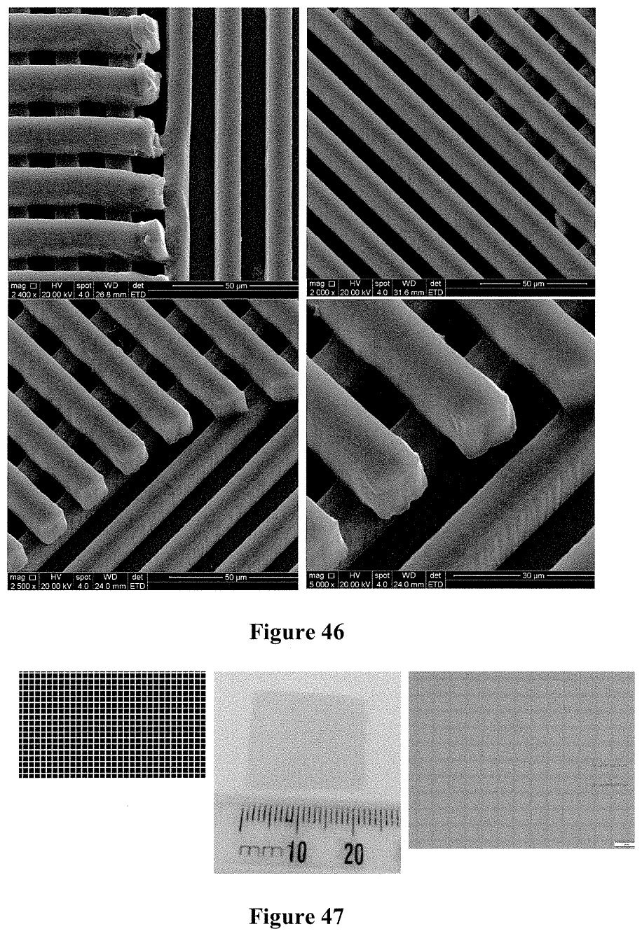

This example, with reference to FIG. 45, is made of two layers including a substrate and tapered sidewalls. The channel was made in 50 μm thick DF-3550 resist laminated onto a polymethyl methacrylate (Perspex) substrate using a Sky 335R6 Pouch Laminator set at 27° C. and using the lowest speed setting. The image was projected with a Texas Instruments DLPDLCR4710EVM-G2 DLP projector (with a 395 nm LED, and InfiniGage main body lens from Edmund optics) and a custom greyscale bitmap pattern for 3 minutes.

After exposure, the channel was cured for 10 minutes at 100° C. on an Electronic Microsystems hotplate, then cooled and developed for 6 minutes in PGMEA.

### Example 3

### High Resolution Prints

This example, with reference to FIG. 46, demonstrates a collection of high resolution 10 μm sided printed bridges.

The bridges were manufactured in EMS DF 3510, 10 μm thick negative dry resist film. Three layers were used: a base layer and two pattern layers. The base layer was wholly exposed (no pattern) with a 5 mW/cm² collimated mercury arc lamp for the source, and an exposure time of 1 minute. Both pattern layers used a prepatterned custom chrome mask photoplate and the 5 mW/cm² collimated mercury arc lamp with a 30 second exposure. After exposing each layer it was laminated to the previous layer with a Sky 335R6 Pouch Laminator set at 50° C. and using the lowest speed setting. An Electronic Microsystems hotplate was used to cure the structures at 100° C. for 10 minutes before removing uncross-linked material by dissolving in PGMEA for 6 minutes.

### Example 4

### Microfabricated Components

These examples demonstrate a series of planar free-standing structures in a collection of microfabricated components.

4a) Mesh

With reference to FIG. 47, a regular crossed square sided mesh made up of wires of 100 μm diameter was fabricated in 20 μm thick DF 2020 using a custom made pattern designed in CleWin5 printed on a 3386 dpi (7 μm) print mask (Agfa HNS polyester film output at 3386 dpi on a Heidelberg Herkules Pro imagesetter). The mesh was exposed for 1 minute using a 5 mW/cm² collimated mercury arc lamp, then heated on an Electronic Microsystems hotplate at 100° C. for 10 minutes before developing in PGMEA.

4b) Microcomponentry

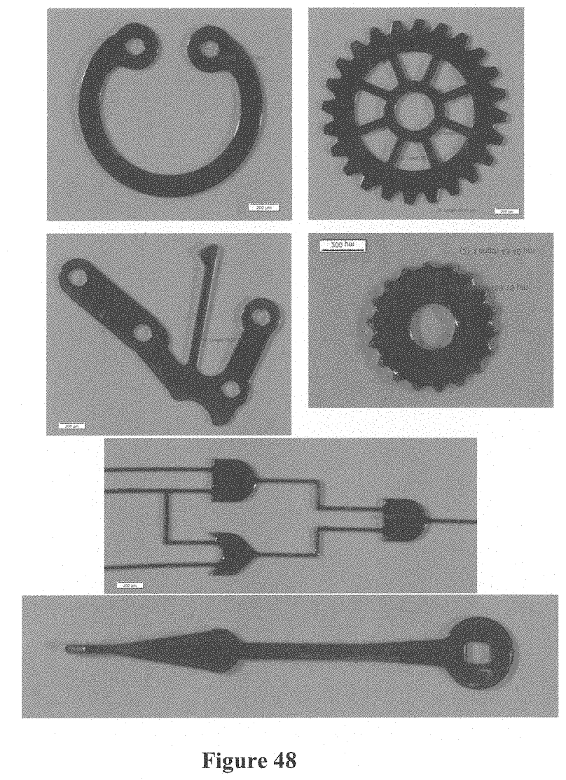

Circlips, microgears, lever springs, needle pointers and logic gates, for example as shown in FIG. 48, were among examples printed in 100 μm thick SUEX D100, with a custom made 3386 dpi (7 μm) print mask (Agfa HNS polyester film output at 3386 dpi on a Heidelberg Herkules Pro imagesetter) from a custom CleWin5 pattern. They were exposed for 2 minutes using 365 nm UV fluorescent tubes and the cured for 10 minutes on a standard 3D printer hotplate at 100° C., before developing in PGMEA. Single layer 100 μm thick structures were produced, with feature sizes down to the 7 μm mask resolution observed.

4c) Stencil

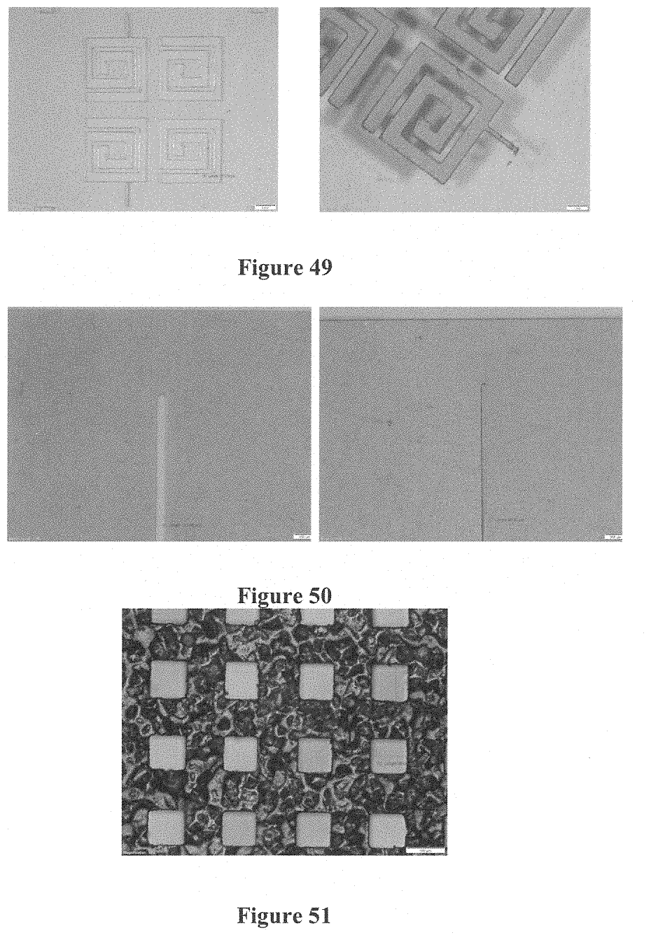

A microwave antenna stencil, with reference to FIG. 49, was fabricated in 150 μm thick negative photoresist SUEX D150. The pattern used was a custom made chrome photomask and the source a collimated mercury arc lamp with an exposure of 30 seconds at an intensity of 5 mW/cm². Following exposure, the stencil was cured on an Electronic Microsystems hotplate for 10 minutes at 95° C., then developed in PGMEA. From the stencil, patterned antenna were made by screen-printing the stencil with silver paint onto an acrylic substrate.

4d) Shadow Masks

With reference to FIG. 50, shadow masks, such as used for ion-beam implantation were fabricated in 50 μm thick EMS DF 3550 dry film resist. The resist was patterned with a 5 mW/cm² collimated mercury arc lamp for 30 seconds using a custom made 3386 dpi (7 μm) print mask (Agfa HNS polyester film output at 3386 dpi on a Heidelberg Herkules Pro imagesetter). After exposure, the shadow masks were cured for 10 minutes using an Electronic Microsystems hotplate, then developed in PGMEA.

4e) Textured Printed Surfaces

Dry film photoresists may be embossed as well as photopatterned. In this example, with reference to FIG. 51, a sheet of 150 μm SUEX was removed from both carrier sheets, then recombined into an assembly with a textured surface on the bottom, in this case P400 grit sandpaper, and a custom made 3386 dpi (7 μm) print mask (Agfa FINS polyester film output at 3386 dpi on a Heidelberg Herkules Pro imagesetter) on the top, laminated pattern side down to the photoresist.

The assembly was laminated in a Sky 335R6 Pouch Laminator set at 67° C. and the lowest speed setting, then exposed with a collimated mercury arc lamp with an exposure of 1 minute at an intensity of 5 mW/cm2. Following exposure, the assembly was heated on an Electronic Microsystems hotplate at 95° C. for 10 mins. After cooling, the sandpaper and print masks were peeled off the cured photoresist and the uncrosslinked material was washed away in PGMEA. The final article retains both the photolithographically patterned structure, as well as the embossed texture.

### Example 5

### Conductive Printing

5a) Patterned Conductive Layers

The use of conductive materials in rapid prototyping enables interfacing with electronic systems and the direct printing of microsensors.

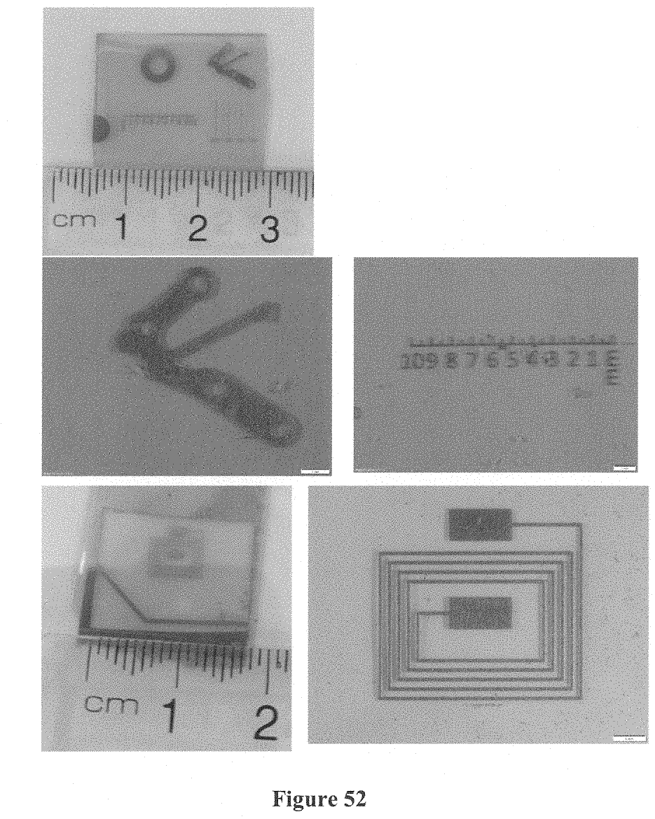

In this example, with reference to FIG. 52, EMS DF-3550, 50 μm negative dry film resist was metallised prior to patterning with a Quorum Technologies SC7640 benchtop SEM sputter coater in 20 nm of an 80:20 gold:palladium mix.

A custom print mask, with resolution 3386 dpi (7 μm) (Agfa HNS polyester film output at 3386 dpi on a Heidelberg Herkules Pro imagesetter) was exposed by a 5 mW/cm² 365 nm collimated mercury arc lamp for 1 minute. The metal is at the bottom of the resist and is opaque to UV light, so that only the resist is patterned. After exposure, the structures were cross-linked by heating on an Electronic Microsystems hotplate at 100° C. for 10 minutes. During this cross-linking stage, the deposited metal nanoparticles are fused to the polymerising resist. During development in PGMEA, uncross-linked resist is washed away, taking with it all metal nanoparticles that have not been fused to a cross-linked polymer. Short bursts of sonication (up to 5 seconds) in an ultrasonic bath helped to remove residual metal nanoparticles.

Example structures include a near-field communication antenna, a metallised lever spring, ruler & micro gear.

5b) Flexible Capacitor:

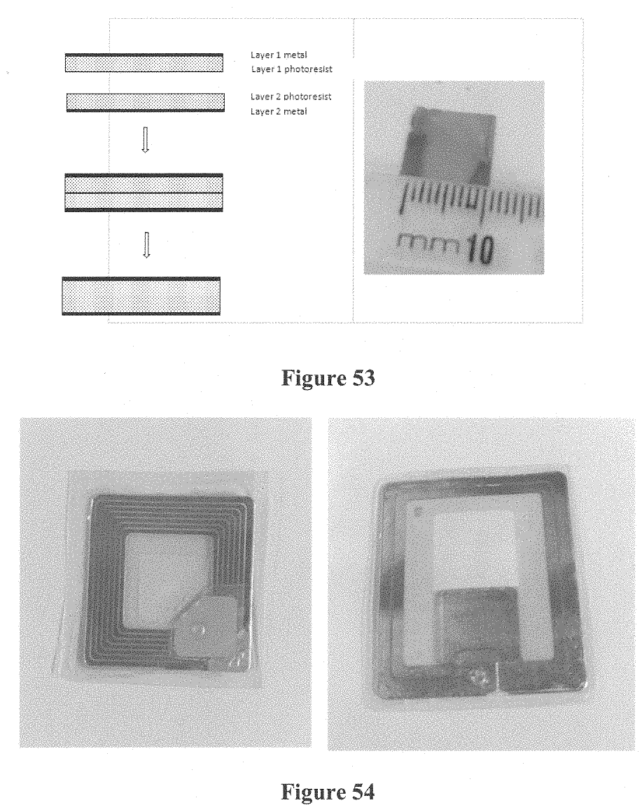

A flexible capacitor, with reference to FIG. 53, was made with two sheets of metallised EMS DF-3550. Each sheet is 50 μm thick, and had been metallised prior to patterning with a Quorum Technologies SC7640 benchtop SEM sputter coater in an 80:20 gold/palladium mix. The capacitor was formed by first exposing the two sheets to a 5 mW/cm2 365 nm collimated mercury arc lamp for 1 minute, then laminating the two sheets with a Sky 335R6 Pouch Laminator set at 27° C. and the lowest speed setting. The assembly, show below has layer 2 with the metal side down and layer 1 with the metal side facing up, laminated together such that the two resist sides face each other, and the two metal sides facing the outside. Following lamination, the assembly was cured for 10 minutes at 100° C. on an Electronic Microsystems hotplate.

The capacitance found as a mean of three measurements at 200 Hz was 50 pF.

### Example 6

### Encapsulated Structures

There is a need to encapsulate devices such as electronics to provide environmental protection. Photoresists are ideal for this purpose due to their high chemical resistance and wide range of thermal operating temperature.

In this example, with reference to FIG. 54, RFID tags were encapsulated in 10 μm thick ADEX A10 by first flood exposing (no pattern) top and bottom covers with a 5 mW/cm² 365 nm collimated mercury arc lamp for 15 seconds. After this, the tags were sandwiched between the two ADEX sheets and laminated with a Sky 335R6 Pouch Laminator set at 27° C. and the lowest speed setting. The laminated assembly was cured for 10 mins at 100° C. on an Electronic Microsystems hotplate then cooled.

### Example 7

### Curved Surfaces

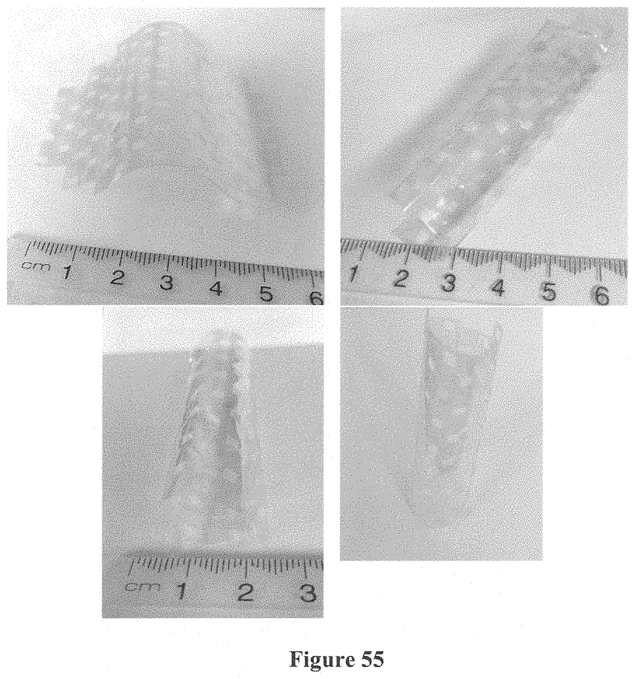

Conventionally, microfabricated structures are planar. In this example, with reference to FIG. 55, single layer curved patterned structures including a parabolic sheet and a cylinder were fabricated in ADEX A50, a 50 μm thick dry film negative photoresist.

Both coversheets were removed and the bare photoresist sheet was exposed using a photomask with a collimated 365 nm mercury arc lamp with an intensity of 5 mW/cm² for the source, and an exposure time of 1 minute. Following exposure, one photoresist sheet was draped over a 20 ml disposable Terumo syringe, and the other wrapped around a 10 ml disposable Terumo syringe and secured with pressure sensitive wafer dicing tape. Both structures were then put into a Contherm Scientific lab oven at 50° C., then ramped to 100° C. over 15 minutes and held at this temperature for a further 5 minutes before cooling and removing the cured photoresist from the syringe. After this, uncrosslinked material was removed by dissolving in PGMEA for 6 minutes. At the end of processing the structures retained the curvature of the syringe template.

### Example 8

### Lens Array

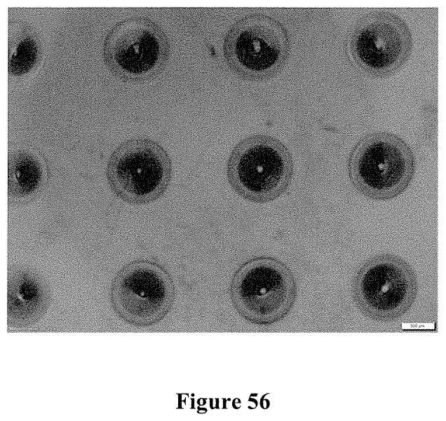

In this example, with reference to FIG. 56, a lens array was formed in 250 μm thick SUEX D250 by the use of a custom made 3386 dpi (7 μm) print mask (Agfa HNS polyester film output at 3386 dpi on a Heidelberg Herkules Pro imagesetter). The resist including cover sheets was exposed for 4½ minutes with using 365 nm UV fluorescent tubes, then the top cover sheet was removed and the patterned resist cured on an Electronic Microsystems hotplate at 100° C. until the uncrosslinked SUEX melted and reflowed, approximately 2 minutes. Once the uncrosslinked SUEX had fully melted, surface tension pulls it into hemispherical structures and these were then crosslinked by a second exposure (with no pattern), this time for 10 minutes to cure the now much thicker structures. The twice exposed assembly was then heated for 15 minutes on the hotplate to finish curing.

If the lens array is not to come into contact with solvents that may dissolve the uncrosslinked material (lenses), a second exposure is unnecessary and may be beneficial to omit as the lens then has better optical transparency. A thermal cure then cool is sufficient to harden the structure.

Unless the context clearly requires otherwise, throughout the description, the words “comprise”, “comprising”, and the like, are to be construed in an inclusive sense as opposed to an exclusive or exhaustive sense, that is to say, in the sense of “including, but not limited to”.

Although this disclosure has been described by way of example and with reference to possible embodiments thereof, it is to be understood that modifications or improvements may be made thereto without departing from the scope of the disclosure. The disclosure may also be said broadly to consist in the parts, elements and features referred to or indicated in the specification of the application, individually or collectively, in any or all combinations of two or more of said parts, elements or features. Furthermore, where reference has been made to specific components or integers of the disclosure having known equivalents, then such equivalents are herein incorporated as if individually set forth.

Any discussion of the prior art throughout the specification should in no way be considered as an admission that such prior art is widely known or forms part of common general knowledge in the field.

1. An apparatus configured to manufacture an article using a photoresist comprising photoresist material, the apparatus comprising:
a. a housing configured to receive the photoresist and locate the photoresist in at least one operational position in the housing;
b. an exposure system configured to emit radiation which is incident on the photoresist material when in the operational position, to induce a change in one or more properties of the area(s) of the photoresist material exposed to the radiation; and
c. a heater configured to heat the photoresist material to cure the photoresist material to the substrate when the photoresist is in the operational position, or is in a different operational position in the housing; wherein
d. the housing is radiation excluding such that external radiation cannot enter the housing at least to the extent that the external radiation is sufficiently excluded from the housing to prevent, or minimise polymerisation of the photoresist material, and further wherein the housing is a clean housing configured to prevent unwanted contamination from entering the housing, at least when the photoresist is located in the or each operational position.

2. The apparatus of claim 1 configured to use a dry film photoresist.

3. The apparatus of claim 1 or claim 2 wherein the apparatus is hand portable.

4. The apparatus of any one of claims 1 to 3 dimensioned and configured as a desk-top apparatus.

5. The apparatus of any one of the preceding claims configured to manufacture an article with feature sizes of 0.5 microns or less, 2 microns or less, four microns or less, or 20 microns or less, and/or a scale of at least 1 cm, 5 cm, 10 cm, 15 centimetres, or 50 cm or more.

6. The apparatus of any one of the preceding claims wherein the exposure system comprises an exposure source, wherein the exposure source comprises a light source selected from any one: a UV fluorescent tube or bulb, an LED or LED array, a laser, a projector, and/or a digital micromirror device (DMD).

7. The apparatus of any one of the preceding claims wherein the exposure source is positioned within the apparatus either above or below the photoresist and can emit radiation onto either or both of the topside or the underside of the photoresist.

8. The apparatus of any one of the preceding claims wherein the exposure system includes one or more radiation manipulators configured to manipulate the radiation between the exposure source and the photoresist.

9. The apparatus of claim 8 wherein the exposure system comprises one or more passive radiation manipulators and/or one or more dynamic or active radiation manipulators.

10. The apparatus of claim 9 wherein the dynamic radiation manipulator include any one or more of a digital mirror, an LCD, a galvanometer and/or an optomechanical laser system.

11. The apparatus of claim 9 wherein the or each passive radiation manipulator includes any one or more of, for example, a mirror, a digital mirror, a prism, a lens, a collimator and/or a beam splitter.

12. The apparatus of claim 9 wherein multiple radiation manipulators are provided.

13. The apparatus of claim 12 wherein the multiple radiation manipulators are provided in series or parallel configuration along the radiation path between the exposure source and the photoresist.

14. The apparatus of any one of the preceding claims wherein the length of the radiation path between the exposure source and the operational position of the photoresist is adjustable.

15. The apparatus of claim 14 further comprising a radiation path length adjuster configured to move one or both of the operational position of the photoresist and the position of the exposure source.

16. The apparatus of any one of the preceding claims wherein the heater comprises any one or more of:
a. a heater plate on which the photoresist is placed or at least adjacent when in the operational position;
b. an infrared heat source configured to radiate the photoresist; and/or
c. an oven in which the photoresist is located when in the operational condition.

17. The apparatus of claim 16 wherein the heater is movably mounted on the apparatus so as to be movable into and out of the operational position.

18. The apparatus of any one of the preceding claims comprising at least one controller configured to control the exposure system and the heater.

19. The controller may be configured to control any one or more of:
a. the intensity, and/or duration and/or timing of the radiation emitted from the exposure system; and/or
b. any one or more of the temperature, duration, timing and/or heating/cooling rate of the heater; and/or
c. an exposure profile and/or a heater profile.

20. The apparatus of claim 18 or claim 19 wherein the controller is configured to receive one or more inputs indicative of one or more properties of the article to be manufactured and/or of the dry film photoresist, and to control the exposure system profile and/or heater profile accordingly.

21. The apparatus of claim 20 wherein the controller is configured to receive a single input being the thickness of the dry film photoresist.

22. The apparatus of claim 20 wherein any one or more of the input(s) to the controller is at least one of: a manual input entered by the user or a measured input determined from one or more sensors provided in or on the apparatus.

23. The apparatus of claim 20 wherein the controller is user programmable such that the user can configure one or more parameters of the controller.

24. The apparatus of any one of the preceding claims comprising an interlock configured to prevent or minimise hazards to the user such as exposure to the UV or other radiation and/or contact with heat by the user while the apparatus is operational.

25. The apparatus of any one of the preceding claims further comprising a developer unit configured to deliver a developer fluid to the photoresist being processed so as to develop the photoresist after curing by the heater to remove either any photoresist material exposed to the developer fluid, or to remove any substrate.

26. The apparatus of any one of the preceding claims wherein the exposure system and the heater are configured to be operative sequentially.

27. The apparatus of any one of claims 1 to 25 wherein the exposure system and the heater are configured to be operative concurrently.

28. The apparatus of any one of the preceding claims comprising a patterning system configured to enable a desired pattern to be applied to the photoresist.

29. The apparatus of claim 28 wherein the patterning system comprises a pattern formed or depicted on a protective sheet of, or applied to the photoresist.

30. The apparatus of claim 28 wherein the patterning system comprises one or more photomasks positioned, or configured to be positioned, between the exposure system and the photoresist.

31. The apparatus of any one of claims 28 to 30 wherein the patterning system is positioned, or configured to be positioned, in direct contact with the photoresist, such that there is no gap between the photoresist and the patterning system.

32. The apparatus of claim 28 wherein the patterning system comprises an electronic pattern configured to control the exposure system to emit radiation in the desired pattern.

33. The apparatus of any one of the preceding claims wherein the photoresist is located in a single operational position during exposure to radiation from the exposure system and during curing by the heater.

34. The apparatus of any one of claims 1 to 32 wherein the apparatus comprises a plurality of operational positions, each of which is associated with one or more processing step of the apparatus.

35. The apparatus of any one of the preceding claims configured to contain only a single photoresist layer, or at least is configured to process only a single photoresist layer at a given time.

36. The apparatus of any one of claims 1 to 34 configured to contain a plurality of photoresist layers.

37. The apparatus of claim 36 comprising a storage device configured to receive and store a plurality of photoresists.

38. The apparatus of claim 37 wherein the storage device is configured to store the plurality of photoresists in a stack, or in a roll or reel.

39. The apparatus of claim 37 or claim 38 wherein the storage device is removeably mounted on the apparatus.

40. The apparatus of any one of the preceding claims further comprising a photoresist feed device configured to feed one or more photoresists into the operational position within the housing of the apparatus.

41. The apparatus of any one of the preceding claims comprising a securing or clamping or locking device provided to secure the photoresist in the operational position, at least until the or some processing steps are complete.

42. The apparatus of any one of the preceding claims configured to process only a single photoresist at a given time.

43. The apparatus of claim 42 configured to sequentially receive a plurality of photoresists, each photoresist being processed in sequence.

44. The apparatus of claim 43 wherein the photoresists are provided in a strip or reel which is fed into the apparatus at a required rate.

45. The apparatus of any one of claims 1 to 44 configured to manufacture an article from multiple photoresists.

46. The apparatus of claim 45 configured to apply one or more further process steps to the photoresists to produce the article, the one or more further process steps being selected from one or more cutting, alignment, laminating and reassembly steps such that the photoresists are layered together in the correct alignment and orientation, to produce the article.

47. The apparatus of any one of claims 43 to 46 configured to simultaneously process multiple photoresist sheets.

48. The apparatus of claim 45 configured to sequentially expose and subsequently cure the multiple photoresists independently, the apparatus being further configured to recombine the patterned elements of the multiple photoresists after exposure to form multilayer structures.

49. A photoresist configured for use with the apparatus of any one of claims 1 to 48, the photoresist comprising photoresist material sandwiched between cover sheets.

50. The photoresist of claim 49 wherein one or both cover sheets is removable.

51. A system for manufacturing an article using dry photoresist comprising a photoresist layer on a substrate, where the substrate may be the photoresist carrier sheet, the system comprising the apparatus of any one of claims 1 to 48, and a photoresist of any one of claims 49 to 50.

52. A method of manufacturing an article using a photoresist comprising a photoresist layer on a substrate, the method comprising steps of:
a. inserting the photoresist into a housing of a manufacturing apparatus;
b. using an exposure system in the housing to emit radiation which is incident on the photoresist material when in the operational position, to induce a change in one or more properties of the area(s) of the photoresist material exposed to the radiation; and
c. controlling a heater, also in the housing, to subsequently heat the photoresist material to cross link the photoresist material to the substrate; wherein
d. the housing is radiation excluding such that external radiation cannot enter the housing at least to the extent that the external radiation is sufficiently excluded from the housing to prevent, or minimise polymerisation of the photoresist material, at least when the photoresist is present, and further wherein the housing is a clean housing configured to prevent unwanted particles and/or other contaminants from entering the housing.

53. The method of claim 52 wherein the photoresist layer can be either used as received as a dry film photoresist, or may be subject to a pre-processing step whereby the apparatus dries the photoresist layer by removal of the solvent, such that the dry photoresist can then be processed as above.

54. The method of claim 52 or 53 comprising using a photoresist comprising of photoresist material sandwiched between cover sheets, or other photoresist such as bare photoresist deposited by means such as spin-coating, dip-coating, doctor-blading.

55. The method of any one of claims 52 to 54 wherein the cover sheets of the photoresist or photoresist cartridge function as a support material specifically to reduce internal stress and maintain smoothness and flatness during processing, and so that a flat, level support is created for the lamination of subsequent potential layers.

56. The method of any one of claims 52 to 55 wherein one of the sheets comprises a UV antireflective material.

57. The method of any one of claims 52 to 56 wherein one or both of the cover sheets functions as a debonding material, for the fast and easy removal of fabricated articles after processing, allowing the production of free-standing structures such as componentry or stencils without the need for etching.

58. The method of any one of claims 52 to 57 wherein one or both sheets comprises a patternable surface for direct contact with the photoresist.

59. The method of any one of claims 52 to 58 wherein one or both carrier sheets comprises an adherent surface configured to provide conformal mask over regions of the photoresist that require protection.

60. The method of any one of claims 52 to 59 comprising a step of forming an active structure such as a cantilever, plate, bridge, or membrane, by selectively bonding part of a layer of one photoresist to another to form a tether, with a flat smooth layer of uncross-linked photoresist material as a support to be removed during development, and leaving another part of the first photoresist free to move, creating the active structure.

61. The method of any one of claims 52 to 60 comprising a step of forming conductive pathways or interfaces within the article.

62. An article manufactured using the apparatus of any of claims 1 to 48 or the method of any one of claims 52 to 61.

63. The article of claim 62 which may be, or comprise, any one or more of:
a. unpatterned encapsulation or wafer bonding;
b. a free-standing structure;
c. a multilayer structure;
d. an aligned multilayer structure;
e. a substrate bound structure that can be either single or multilayer, aligned or not;
f. an active structure formed by the combination of partly bound and partly free-standing structures. Such an active structure may thus include a part or region that can move relative to another;
g. a structure that includes conductive elements;
h. an active structure that includes conductive elements.
i. a structure that contains transducer elements;
j. an active structure formed with the combination of transducer and conductive elements.

64. The article of claim 62 or claim 63 including the unpatterned encapsulation of electronics such as antennae, circuit boards, or electronic microcomponents.

65. The article of claim 63 wherein single layer free-standing micro-componentry include miniature gears, cog wheels, springs, clips, lens holders, and stencils.

66. The article of claim 63 wherein substrate bound structures include microstructured templates for precision stamps, electroplating, injection moulding, embossing, and soft lithography.

67. The article of claim 63 wherein multilayer microstructures include hydrophobic surfaces, “gecko feet” type surfaces which may be used for precision robotics; or microfluidic chips.

68. The article of claim 63 wherein active structures include cantilevers, plates, bridges, and membranes which are formed by selectively bonding part of a first photoresist to another photoresist to form a tether, while leaving part of the first photoresist free to move.

69. The article of claim 63 wherein active structures include springs which are the basic components of MEMS springs, from which microsensors can be fabricated when combined with conductive and/or piezoelectric materials.

70. An apparatus substantially as described herein and as shown in any one of FIGS. 2 to 7.

71. An apparatus substantially as described herein and as shown in FIG. 8.

72. An apparatus substantially as described herein and as shown in FIGS. 10 to 16.

73. A system substantially as described herein and as shown in any one of FIGS. 1 to 7.

74. An article substantially as described herein.

75. A method substantially as described herein and as shown in any of FIGS. 1 to 38.
